(19) United States
(12) Patent Application Publication
(10) Pub. No.: US 2016/0354997 A1
(43) Pub. Date: Dec. 8, 2016

(54) WATER-PROOF AND DUST-PROOF MEMBRANE ASSEMBLY AND APPARATUS USING THE SAME

(71) Applicant: EF-MATERIALS INDUSTRIES INC., Zhongli City (TW)

(72) Inventors: James Huang, ZHONGLI CITY (TW); Sean Chen, ZHONGLI CITY (TW); Radium Huang, ZHONGLI CITY (TW); Jeff Han, ZHONGLI CITY (TW); Yu Pin Lin, ZHONGLI CITY (TW)

(73) Assignee: EF-MATERIALS INDUSTRIES INC., ZHONGLI CITY (TW)

(21) Appl. No.: 15/243,199

(22) Filed: Aug. 22, 2016

Related U.S. Application Data
(63) Continuation-in-part of application No. 13/682,512, filed on Nov. 20, 2012.
Application No. 13/682,512 is a continuation-in-part of application No. 12/842,193, filed on Jul. 23, 2010.
Application No. 12/842,193 is a continuation-in-part of application No. 12/732,571, filed on Mar. 26, 2010, now Pat. No. 8,530,004.

(51) Int. Cl. B32B 27/06; B01D 69/02; B01D 69/12; B01D 71/26; B65D 43/02; B01D 69/10; F21V 31/00; H05K 5/02; F21V 21/00; B65D 25/54; B01D 67/00; B01D 71/36

(52) U.S. Cl. CPC B32B 27/065; B01D 67/0083; B01D 69/02; B01D 69/12; B01D 71/26; B01D 71/36; B01D 69/10; F21V 31/005; H05K 5/02; F21V 21/00; B65D 25/54; B65D 43/02; B01D 2325/02; B01D 2325/022; B01D 2325/04; B01D 2325/20; B01D 2325/38; B32B 2457/00; B32B 2307/7265; B32B 2305/022

(57) ABSTRACT

A water-proof and dust-proof membrane assembly which has a satisfactory water-proof property, dust-proof property, sound transmission capability and air permeability, as well as excellent supporting intensity and pressure resistance is provided. A water-proof and dust-proof membrane assembly having a body and a supporting member, in which the body is an asymmetric porous structure in the form of membrane having a first surface and a second surface, the supporting member is composed of a polymeric material, includes a first contact surface and a second contact surface and the porosity (second porosity) of the supporting member is larger than the first porosity, i.e. 10% to 99.9%, and the first surface of the body and the first contact surface of the supporting member are bonded is provided.

### CROSS-REFERENCE TO RELATED APPLICATIONS

This application is a continuation-in-part of U.S. application Ser. No. 13/682,512, filed Nov. 20, 2012, which is a continuation-in-part of U.S. application Ser. No. 12/842,193, filed Jul. 23, 2010, which is a continuation-in-part of U.S. application Ser. No. 12/732,571, filed Mar. 26, 2010 (now U.S. Pat. No. 8,530,004 issued Sep. 10, 2013), which claims priority to Taiwan Application No. 099102950 filed on Feb. 2, 2010, the complete disclosures of which, in their entireties, are herein incorporated by reference.

### TECHNICAL FIELD

The present invention relates to water-proof and dust-proof membrane assembly and an apparatus using the assembly.

### BACKGROUND ART

The advancement of science has improved the quality of human life and has made electronic products essential to human life. Examples of such electronic products are consumptive electronic products such as cell phones, digital cameras, MP3 players, MP4 players, PDAs and the like: general outdoor electronic products such as security monitoring camera systems, outdoor lightings, traffic lights, underwater electronic products, marine electronic products, telecommunication devices and the like: and medical electronic products.

Housings of various outdoor electronic products are always exposed to temperature variation, weather corrosion and solar radiation. Also, sudden drop of the ambient temperature causes unbalanced air pressure between the inside and the outside of the housing. For this reason, air or moisture enters the housing and electronic circuits which are sensitive to air and moisture cause corrosion inside the housing, thereby inducing breakdown or damage. In addition, consumptive electronic products without water-proof and dust-proof functions are, when splashed by water or other liquids accidentally or when frequently used, likely to get damaged because of liquids or dust entering into the electronic circuit thereof. Therefore, the related manufacturers have paid much attention to continuously improve practicability and durability of the existing electronic products.

One major factor for prolonging the service life of electronic products is to keep internal electronic circuits functioning normally. In order to ensure the sensitivity of electronic products, to secure normal operation of their internal electronic circuit and further, to enable the electronic products to continue good operation even in adverse circumstances, factors including water-proof function, dust-proof function, corrosion resistance and air permeability need to be further considered.

Currently, it is common to use a porous film as a protective film. Specifically, many porous films are made of fluorinated polymeric materials such as fluoropolymer, fluorinated ethylene-propylene copolymer (FEP), polytetrafluoroethylene (PTFE) and polyvinylidene fluoride (PVDF).

Porous PTFE films have excellent water repellency at its surface and show the largest water contact angle among the above materials. Therefore, the porous PTFE films are hardly wetted by general liquids and hardly bonded to other materials.

A porous PTFE film is produced according to a disclosed process (for example, Patent Documents 1 to 3). The obtained porous PTFE film can be made into a porous film with 1 billion to 15 billion micro-pores per square inch which has excellent air permeability. Further, the above porous PTFE film has an average pore size of 0.25 to 0.55 μm, which is ten-thousandth as large as a raindrop while 700 times larger than a sweat vapor molecule or a water vapor molecule, and thus the porous PTFE film is advantageous as an air permeable and water-proof film.

The internal network structure formed with the microfibers of the porous PTFE film has heat resistance and surface lubricity in nature, and dust adsorbed on the film surface can be easily removed. The above porous PTFE film may be made with different pore sizes and laminated with various fabrics for being used for materials requiring dust-proof function. Therefore, the porous PTFE film is useful for dust-proof and filtering purposes.

A protective film of this kind prepared from a porous PTFE film having water-proof property, sound transmission capability, dust-proof property and air permeability needs to be provided with different levels of water-proof property, sound transmission capability and air permeability when applied to different products. It is known that the water-proof property of the porous PTFE film is enhanced by decreasing the average pore size thereof. However, water-proof property and air permeability usually spoil each other's performance; in other words, water-proof property and air permeability are in a trade-off relationship (for example, Patent Documents 4 to 5). In addition, sound transmission capability and water-proof property are also in a trade-off relationship. To be brief, a decreased average pore size lowers air permeability as well as sound transmission capability. Accordingly, it is not easy to enhance the water-proof property without lowering air permeability and sound transmission capability. While there are commercially available protective film products made of a porous PTFE film, one with high air permeability and high sound transmission capability has a relatively large pore size, which suggests weakened water-proof property. On the other hand, one having a relatively small pore size to present good water-proof property often suffers from lowered air permeability and sound transmission capability.

Patent Document 6 discloses an asymmetrical porous PTFE film. However, in such invention, properties having a trade-off relationship cannot be improved simultaneously.

### PRIOR ART DOCUMENT

### Patent Document

[Patent Document 1] The U.S. Pat. No. 3,953,566

[Patent Document 2] The U.S. Pat. No. 3,962,153

[Patent Document 3] The U.S. Pat. No. 4,902,423

[Patent Document 4] Japanese Unexamined Patent Application Publication No. 2009-501632

[Patent Document 5] Japanese Unexamined Patent Application Publication No. 1990-284614

[Patent Document 6] The United States Patent Application No. 2003/0089660

### DISCLOSURE OF THE INVENTION

### Problem to be Solved by the Invention

The above common electronic products and water-proof electronic products need an appropriate protective film made of a porous PTFE film for protecting the internal electronic circuits, and many non-electronic products with special requirements regarding water-proof capability and air permeability also need such protective film. Therefore, a problem to be solved by the invention is how to make a protective film for protecting products and prolonging the service life of the products, which has satisfactory water-proof property, dust-proof capability and air permeability, and is adaptive to various products.

### Means for Solving the Problem

Accordingly, a main object of the present invention is to provide a water-proof and dust-proof membrane assembly which has a satisfactory water-proof property, dust-proof property, sound transmission capability and air permeability, as well as excellent supporting strength and pressure resistance.

In order to solve the above problem, the present invention provides a water-proof and dust-proof membrane assembly, which comprises a body and a supporting member. The body is an asymmetric porous structure in the form of membrane having a first surface and a second surface. The asymmetric porous structure has a thickness of 1 to 1,000 μm, a porosity (first porosity) of 5% to 99%, a pore size of each pore of 0.01 to 15 μm, a Frazier air permeability of 8.0 ft³/minft² to 250 ft³/minft², a Gurley number of 0.3 to 25 seconds, a Water Resistance of 1000 mmH₂O to 23000 mmH₂O and a Sound Transmission Loss 0.5 dB to 2.0 dB. The supporting member is composed of a polymeric material, and includes a first contact surface and a second contact surface. The porosity (second porosity) of the supporting member is greater than the first porosity, i.e. 10% to 99.9%, and the first contact surface of the supporting member is bonded to the first surface of the body.

According to the present invention provided with such a configuration as mentioned above, “water-proof property and air permeability” and “sound transmission capability and water-proof property”, each of which are in a trade-off relationship, can be enhanced simultaneously. Namely, in the present invention, the asymmetric porous structure has a predetermined thickness, and a porosity, a pore size of a pore, a Frazier air permeability, a Gurley number, a water resistance and a sound transmission loss are within a predetermined numerical range. Therefore, the above-mentioned “water-proof property and air permeability” and “sound transmission capability and water-proof property”, each of which are in a trade-off relationship, can be enhanced simultaneously.

The asymmetric porous structure has a dense skin layer and a continuously foamed porous layer and it is preferable that the skin layer makes up 0.04 to 40% of the thickness of the asymmetric porous structure. It is also preferable that the water contact angle of the skin layer is 120° to 135°.

The asymmetric porous structure may have the skin layer on the surface of either the first surface or the second surface and, a Frazier air permeability of 8.0 ft³/minft² to 200 ft³/minft², a Gurley number of 0.3 to 25 seconds, a Water Resistance of 1000 mmH₂O to 18000 mmH₂O and a Sound Transmission Loss 0.5 dB to 2.0 dB. Also, the asymmetric porous structure may have the skin layer on the both surfaces of the first surface and the second surface and, a Frazier air permeability of 15 ft³/minft² to 250 ft³/minft², a Gurley number of 0.3 to 25 seconds, a Water Resistance of 11000 mmH₂O to 23000 mmH₂O and a Sound Transmission Loss 0.5 dB to 1.5.

The asymmetric porous structure is produced by heat-treating a symmetric porous structure, and it is preferable that the Frazier air permeability after the heat treatment is 1.1 to 2.5 times that before the heat treatment.

The collecting efficiency of the asymmetric porous structure is preferably 99.50 to 99.99%.

In the water-proof and dust-proof membrane assembly using the asymmetric porous structure in which the skin layer is provided on either of the first surface side or the second surface side, it is preferable that its Frazier air permeability is 6.0 ft³/minft² to 183 ft³/minft², its Gurley number is 0.25 to 25 seconds, its Water Resistance is 3,000 mmH₂O to 20,000 mmH₂O and its a Sound Transmission Loss is 0.7˜3.0 dB.

In the water-proof and dust-proof membrane assembly using the asymmetric porous structure in which the skin layer is provided on either of the first surface side and the second surface side, it is preferable that its Frazier air permeability is 12.6 ft³/minft² to 220 ft³/minft², its Gurley number is 0.3 to 25 seconds, its Water Resistance is 13,000 mmH₂O to 25,000 mmH₂O and its a Sound Transmission Loss is 0.7˜3.0 dB.

The body is preferably formed by a film selected from a resin porous film or a fluorine-containing polymer film. The preferable resin porous film is an ultrahigh molecular weight porous polyethylene film or a polytetrafluoroethylene film, and the preferable fluorine-containing polymer film is one prepared from a partially fluorinated polymer or a completely fluorinated polymer.

It is another object of the present invention to provide a water-proof and dust-proof membrane assembly, which has excellent supporting strength and pressure resistance and thereby being adaptive to underwater products.

Further, it is yet another object of the present invention to provide an electronic device and a lighting system provided with the water-proof and dust-proof membrane assembly having satisfactory water-proof property, dust-proof property, sound transmission capability as well as air permeability.

### Effect of the Invention

The water-proof and dust-proof membrane assembly of the present invention is provided with a body and a supporting member. The body is an asymmetric porous structure in the form of membrane having a first surface and a second surface. The asymmetric porous structure has a thickness of 1 to 1,000 μm, a porosity (first porosity) of 5% to 99%, a pore size of each pore of 0.01 to 15 μm, a Frazier air permeability of 8.0 ft³/minft² to 250 ft³/minft², a Gurley number of 0.3 to 25 seconds, a Water Resistance of 1000 mmH₂O to 23000 mmH₂O and a Sound Transmission Loss 0.5 dB to 2.0 dB. By using such body, it is possible to provide a water-proof and dust-proof membrane assembly which has a satisfactory water-proof property, dust-proof property, sound transmission capability and air permeability, without losing the performances which are generally in a trade-off relationship, such as water-proof property and air permeability or sound transmission capability and water-proof property.

Moreover, the water-proof and dust-proof membrane assembly is provided with a supporting member. As a result, it is possible to provide a water-proof and dust-proof membrane assembly which has excellent supporting strength and pressure resistance.

### BRIEF DESCRIPTION OF THE DRAWINGS

FIG. 1 is a schematic sectional view of the water-proof and dust-proof membrane assembly according to a first embodiment of the present invention.

FIG. 2 is a schematic sectional view of the water-proof and dust-proof membrane assembly according to a second embodiment of the present invention.

FIG. 3 is a schematic sectional view of the water-proof and dust-proof membrane assembly according to a third embodiment of the present invention.

FIG. 4 (a) is a schematic view explaining the way of heat treatment for forming a skin layer in the water-proof and dust-proof membrane assembly according to a third embodiment of the present invention.

FIG. 4 (b) is a schematic view explaining the other way of heat treatment for forming a skin layer in the water-proof and dust-proof membrane assembly according to a third embodiment of the present invention.

FIG. 5(a) is a schematic view of a cell phone has a housing using the water-proof and dust-proof membrane assembly of the present invention.

FIG. 5(b) is a schematic view of a cell phone has a housing using the water-proof and dust-proof membrane assembly 10 the present invention is located at each opening.

FIG. 6 is a schematic view of an underwater digital camera using the water-proof and dust-proof membrane assembly of the present invention.

FIG. 7 is a schematic view of a lighting system using the water-proof and dust-proof membrane assembly of the present invention.

FIG. 8 is a schematic view of a container using the water-proof and dust-proof membrane assembly of the present invention.

FIG. 9 is a graph evaluating the relation between the Gurley number and the sound transmission loss of the membrane of asymmetric porous structure of the present invention.

FIG. 10 is a graph evaluating the relation between the Gurley number and the water pressure resistance (water intrusion pressure) of the membrane of asymmetric porous structure of the present invention.

### EMBODIMENT FOR CARRYING OUT THE INVENTION

In the present invention, an asymmetric porous structure in which a skin layer is provided on one surface of a continuously foamed porous structure (hereinafter, also referred to as a single skin membrane) (embodiments 1 and 2) or an asymmetric porous structure in which a skin layer is provided on both surfaces of a continuously foamed porous structure (hereinafter, also referred to as a sandwich skins membrane) (embodiment 3) is used.

The single skin membrane and the sandwich skins membrane have overcome the above-mentioned problem of trade-off relationship and have satisfactory air permeability, water-proof property and sound transmission capability, while the reason is not necessarily clear.

The asymmetric porous structure is provided with the skin layer by heat-treating the continuously foamed porous structure. In the present invention, it is considered that the problem of trade-off relationship has been overcome by using the asymmetric porous structure having the appropriate amount and property of the skin layer which is formed by controlling the condition of the heat treatment. For example, the water contact angle of the continuously foamed porous layer of polytetrafluoroethylene is 115° to 118°. On the other hand, the water contact angle of the skin layer on the surface of the single skin layer is about 120° to 135° and which is quite high. That is, it is considered that due to the heat treatment, the surface structure of the skin layer is widely varied from the surface structure of the raw material film. This variation of the surface structure provides the asymmetric porous structure with satisfactory air permeability, water-proof property and sound transmission capability.

The sandwich skins membrane has more excellent air permeability, water-proof property, sound transmission capability and the like than the single skin membrane. The sandwich skins membrane provides skin layers on the both surfaces of the continuously foamed porous layer and thereby the effect of heat treatment is given on the both surfaces. Further, in the sandwich skins membrane, an expanding process is carried out after the skin layers are provided by the heat treatment and this expanding process is considered to contribute to further structural variation of the membrane.

In the expanding process, the whole membrane is expanded in e.g. the transverse direction of the membrane and thereby the structure of the continuously foamed porous layer other than the skin layers is also varied. Specifically, this structural variation include a shape variation or loosening of nodes existing in the continuously foamed porous layer other than the skin layers, a shape variation or cutting of fibril which connects each node, and an increase of fibril due to the loosening of the nodes.

This structural change has the following effects for example. That is, in the case where the area of nodes is large, the deformation of nodes deflects the flow path of air and complicates the same, thereby lengthening the total flow path. If the nodes are loosened, the large area of the nodes is decreased to simplify the flow path of air as well as relatively increase the number of the flow paths. Moreover, generated fibril in accordance with the loosening of nodes stimulates simplification of the flow path of air as well as increases the number of flow paths. Additionally, the deformation or cutting of fibril which connects nodes also causes the increase or simplification of the flow path of air.

In this manner, due to the two processes of the heat treatment and the expanding process, the sandwich skins membrane is considered to have more excellent air permeability, water-proof property, sound transmission capability and the like than the single skin membrane.

### Embodiment 1

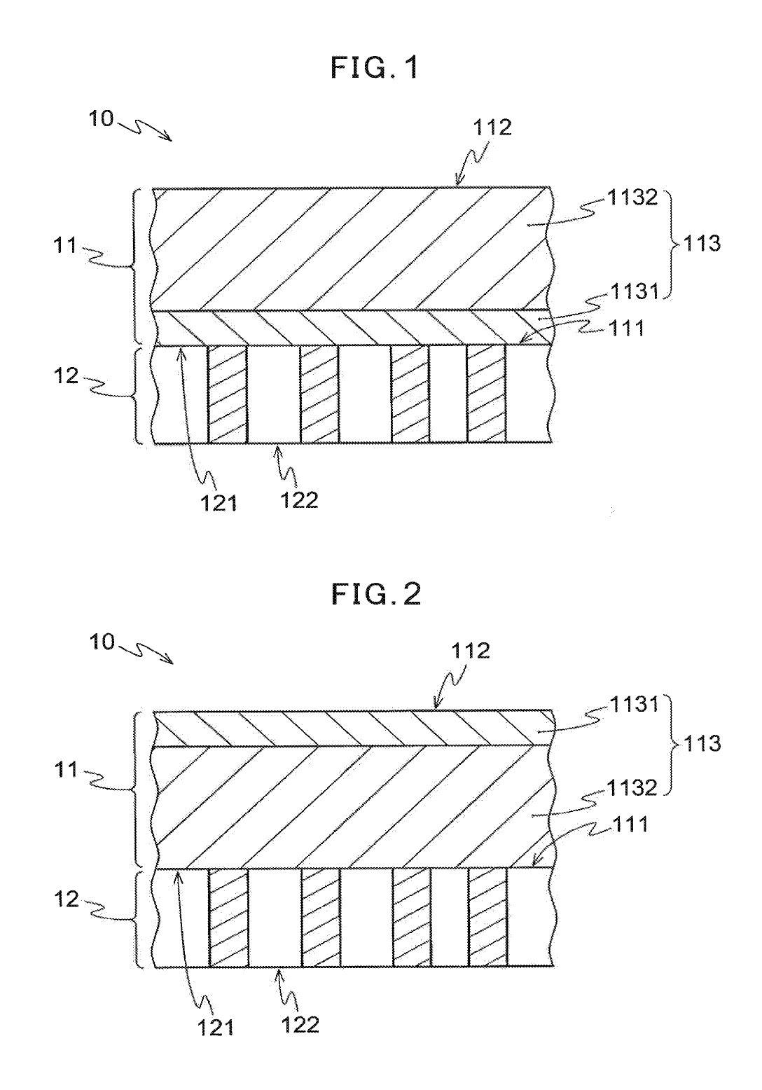

Hereinafter, the water-proof and dust-proof membrane assembly according to the first embodiment of the present invention will be explained using the drawings. FIG. 1 is a schematic sectional view of the water-proof and dust-proof membrane assembly according to the first embodiment of the present invention. As shown in FIG. 1, the water-proof and dust-proof membrane assembly 10 according to the first embodiment of the present invention has a body 11 and a supporting member 12. The body 11 is an asymmetric porous structure 113 in the form of membrane having a first surface 111 and a second surface 112. The asymmetric porous structure 113 in the form of membrane is composed of a skin layer 1131 and a continuously foamed 1132. The supporting member 12 is composed of a polymeric material and includes a first contact surface 121 and a second contact surface 122. The body 11 and the supporting member 12 are bonded to each other between the first surface 111 of the body and the first contact surface 121 of the supporting member.

[Body]

(Material)

A material of the body is not limited as long as the material can form an asymmetric porous structure in the form of membrane. Preferable materials are resins such as an ultrahigh molecular weight polyethylene and polytetrafluoroethylene, and fluorine-containing polymers such as a partially fluorinated polymer and a completely fluorinated polymer (except polytetrafluoroethylene). Among these, an especially preferable material is polytetrafluoroethylene (hereinafter, referred to as “PTFE”), and a method of forming the asymmetric porous structure 113 in the form of membrane using PTFE will be explained below.

In the specification, a symmetric porous film refers to the one in which pores having a defined average pore size exist over the film uniformly. Further, the asymmetric porous structure 113 refers to the one having a surface (skin surface 1131) whose porous structure is further densified by heat-treating the surface of the symmetric porous film. The continuously foamed porous layer refers to the one that while heat treatment the pore diameter and pore structure of the symmetric porous film remain substantially unchanged.

The asymmetric porous structure 113 used in this embodiment can be produced basically according to the following six known processes.

(1) Paste Extrusion Process of PTFE Fine Powder

A paste mixture of PTFE fine powder obtained by an emulsion polymerization method and extrusion aids such as naphtha is extruded with an extruder to obtain an extrudate in the form of column, rectangular column or sheet.

Here, PTFE fine powder is the dried powder of a polymer separated by coagulating aqueous dispersion of the polymer obtained by an emulsion polymerization method. The composition of the polymer is a tetrafluoroethylene (TFE) homopolymer or a copolymer (modified PTFE) comprising TFE and a small amount, generally 0.5 weight % or less of perfluoroalkylvinylether, hexafluoropropylene or the like.

In this process, it is preferable that the orientation of PTFE is inhibited as much as possible, since the following expanding process can proceed smoothly. The inhibition of the orientation can be achieved by appropriately selecting a reduction ratio (a preferable range is 100:1 or less, and normally 20 to 60:1), a proportion of PTFE/extrusion aid (normally 77/23 to 80/20), a die angle of the extruder (normally approximately 60°) and the like in the extrusion of the paste.

(2) Rolling Process of the Paste Extrudate

The paste extrudate obtained in the process (1) is rolled in the extrusion direction or the orthogonal direction of the extrusion direction with a calendar roll or the like to be made into a sheet form.

(3) Removing Process of the Extrusion Aid

The extrusion aid is removed by heating the rolled object obtained in the process (2) or by extraction using a solvent such as trichloroethane, trichloroethylene or the like.

Though the heating temperature can be selected as needed according to an extrusion aid, it is preferable that the temperature is 200 to 300° C. In particular, it is preferable to conduct the heating at approximately 250° C. When the temperature exceeds 300° C., especially 327° C. which is the melting point of PTFE, the rolled object tends to be sintered.

(4) Expanding Process

The rolled object without extrusion aids obtained in the process (3) is expanded in the uniaxial direction or biaxial directions. The rolled object can be preheated to approximately 300° C. before the expanding. Additionally, when conducting a biaxial expanding, both of consecutive expanding and simultaneous expanding are possible.

The expanding ratio should be selected carefully, since it affects the tensile strength and the like of the film. The ratio is normally in the range between 300 to 1,000% in the area ratio, and preferably 400 to 800%. When the ratio is lower than 300%, a desired pore size and porosity tend not to be able to be obtained, and when the ratio is higher than 1,000%, a desired pore size and porosity also tend not to be able to be obtained.

(5) Heat-Setting Process

The expanded object obtained in the process (4) is heat-treated for a relatively short period of time (5 to 15 seconds) at 340 to 380° C., which is the temperature a little higher than the melting point of PTFE (approximately 327° C.) and lower than the decomposition temperature thereof, to be heat-set. When the temperature is lower than 340° C., the setting is not enough, and when the temperature is higher than 380° C., the heat-setting time becomes short and the control of the time tends to be difficult.

(6) Skin Layer Forming Process

In the present invention, an asymmetric porous PTFE film is produced by cooling one surface of the expanded porous PTFE film obtained in the above manner while heat-treating the other surface and subsequently cooling.

At this time, the heating condition is such that the expanded porous PTFE film is heat-treated at 260° C. to 380° C., preferably 340° C. to 360° C. for 1 to 15 seconds, preferably 1 to 5 seconds. When the heat-treating temperature is lower than 260° C., the formation of the skin layer 1131 tends to become not enough. On the other hand, when the temperature exceeds 380° C., the thickness of the skin layer 1131 becomes excessive and sound transmission capability and air permeability tend to be reduced.

As described above, by heat-treating one surface of the heat-set symmetric porous PTFE film once again, only the one surface of the film is modified and an asymmetric porous PTFE film having a porous structure, an improved surface roughness and a large water contact angle and the like can be obtained.

Regarding the porous structure, according to SEM photograph, a conventional symmetric porous PTFE film wholly forms an approximately uniform porous structure. On the other hand, in the asymmetric porous PTFE film of the present invention, the skin layer 1131 is formed as a dense layer and the porous layer 1132 has the porous structure similar to that of the conventional symmetric porous PTFE film. Further, the porosity of the whole film is 5 to 90%, preferably 20 to 90%, and more preferably 50 to 90%. Considering that the porosity of the symmetric porous PTFE film is 45 to 90%, it is recognized that the film is considerably densified. When the porosity is less than 5%, an amount of air permeation is reduced and thereby the air permeability is weakened, while the water-proof property is reduced when the porosity exceeds 90%. Here, the porosity is obtained from the measurement of density, using the following formula:

Porosity (%)=(1−PTFE apparent density/PTFE true density)×100, wherein the PTFE apparent density (g/cc)=weight (W)/volume (V) of the porous PTFE film, and the true density (g/cc)=2.15(literature data).

The pore size of the porous layer of the asymmetric porous PTFE film of the present invention is 0.01 to 15 μm, preferably 0.05 to 10 μm, and more preferably 0.2 to 3 μm. In the specification, the pore size is measured according to the method of ASTM F316. When the pore size is smaller than 0.01 μm, an amount of air permeation is reduced and thereby air permeability and sound transmission capability are reduced, while water-proof property is reduced when the pore size exceeds 15 μm. Moreover, it is preferable that the pore size of the porous layer 1132 is 0.04 to 0.80 μm.

First, regarding the symmetric porous PTFE film and the asymmetric PTFE film obtained by heat-treating thereof, it is ensured from the SEM photographs (×20000 magnification) that the pore sizes, the structures and the like of the porous layers before and after the heat treatment have not changed. One of characters of the present invention is that after the heat treatment, the pore size, structure and the like of the porous layer 1132 do not change but the skin layer 1131 is modified.

In addition, when preparing the asymmetric porous structure 113 of the present invention, other mixtures may be added. The additives to be mixed are titanium dioxide, silicon dioxide, carbon black, carbon nanotube, inorganic oxide and organic oxide. These additives may be used independently or may be used in combination of two or more thereof. The content of the additives is approximately 15 to 30%.

The asymmetric porous structure 113 used in the present invention has a thickness of, for example, 1 to 1,000 μm, preferably 5 to 500 μm, and more preferably 10 to 200 μm. When the thickness of the asymmetric porous structure 113 is less than 1 μm, the mechanical strength thereof is not enough and therefore lacks practicability. On the other hand, when the thickness of the asymmetric porous structure 113 is more than 1,000 μm, air permeability thereof decreases.

The asymmetric porous structure 113 used in the present invention has a Frazier air permeability of 8.0 to 250 ft³/minft² and preferably 15 to 200 ft³/minft².

When the Frazier air permeability is less than 8.0 ft³/minft², for example, there is a tendency that it becomes difficult to equilibrate an inside pressure and an outside pressure of a housing of an electronic/electrical product at a given speed. Further, the sound transmission loss tends to increase. Furthermore, in order to feed in and out a target amount of air in a given period of time, a further wider air permeation area is required. As a result, there is a problem with a design of a housing of an electronic/electrical product. On the other hand, when the Frazier air permeability exceeds 250 ft³/minft², air easily flows into the inside of the housing of the product from the outside, and as a result of this inflow of the air, moisture in the outside air may be fed in together, which leads to a problem from the viewpoint of protection of an electronic/electrical product. Further, the collecting efficiency which is in a trade-off relationship with the air permeability deteriorates, which causes outside dusts to easily flow into the housing. As a result, contamination and corrosion of built-in electronic parts may arise.

In this embodiment, the Frazier air permeability can be adjusted to be within the above-mentioned numerical range by adjusting a thickness, a pore size of a pore, a porosity, and the like of the symmetric porous PTFE film to be used according to the expanding conditions and thereafter forming a skin layer by adjusting a temperature, a time and the like in the above-mentioned step (6).

Measurement of Frazier Air Permeability

Frazier air permeability is measured according to ASTM D-737-04.

The asymmetric porous structure 113 used in the present invention having the following properties is obtained by treating a symmetric porous structure which has a Gurley number of 0.3 to 25 seconds, preferably 0.5 to 2.5 seconds, and more preferably 0.6 to 1.0 second under the above conditions. The Gurley number is measured according to the method of JIS P8117.

When the Gurley number is less than 0.3 second, air easily flows into the inside of the housing of a product from the outside, and as a result of this inflow of the air, moisture in the outside air may be fed in together, which leads to a problem from the viewpoint of protection of an electronic/electrical product. Further, the collecting efficiency which is in a trade-off relationship with the air permeability deteriorates, which causes outside dusts to easily flow into the housing. As a result, contamination and corrosion of built-in electronic parts may arise. On the other hand, when the Gurley number exceeds 25 seconds, for example, there is a tendency that it becomes difficult to equilibrate an inside pressure and an outside pressure of a housing of an electronic/electrical product at a given speed. Further, the sound transmission loss tends to increase. Furthermore, in order to flow in and out a target amount of air in a given period of time, a further wider air permeation area is required. As a result, there is a problem with a design of a housing of an electronic/electrical product.

In this embodiment, the Gurley number can be adjusted to be within the above-mentioned numerical range by adjusting a thickness, a pore size of a pore, a porosity, and the like of the symmetric porous PTFE film to be used according to the expanding conditions and thereafter forming a skin layer by adjusting a temperature, a time and the like in the above-mentioned step (6).

Further, when the skin layer 1131 is formed on the first surface of the continuously foamed porous layer 1132, it is preferable that the skin layer makes up 0.04 to 40% of the thickness of the asymmetric porous structure 113. By providing the skin layer 1131 in this proportion, the function of the water-proof and dust-proof membrane assembly 10 of the present invention can be achieved.

Moreover, in the water-proof and dust-proof membrane assembly 10 of the present invention, it is preferable that the water contact angle of the skin layer 1131 is 120° to 135°. When the water contact angle of the skin layer 1131 is within this range, the water-proof and dust-proof membrane assembly 10 of the present invention has enough water-proof property.

Here, contact angle was calculated by using a contact angle measuring machine CA-D made by Kyowa Interface-science Co., Ltd. according to the following equation:

Water contact angle=2 tan⁻¹(h/r), wherein h=the height of spherical water droplet and r=the radius of the droplet.

The asymmetric porous structure 113 is produced by heat-treating a symmetric porous structure, and it is preferable that the Frazier air permeability after the heat treatment is 1.1 to 2.5 times that before the heat treatment, preferably 1.2 to 2.0, and more preferably 1.3 to 1.9. The water-proof and dust-proof membrane assembly 10 of the present invention increases air permeability by providing the skin layer 1131 on the symmetric porous structure 1132. From this, the water-proof and dust-proof membrane assembly 10 having enough air permeability can be obtained.

The sound transmission loss of the asymmetric porous structure 113 according to the water-proof and dust-proof membrane assembly 10 of the present invention is 0.5 to 2.5 dB, preferably 0.5 to 2.0 dB, and more preferably 0.5 to 1.3 dB. In this manner, the water-proof and dust-proof membrane assembly 10 of the present invention has high sound transmission capability while having high water-proof property. The sound transmission loss is measured according to the method of IEEE269.

When the sound transmission loss is less than 0.5 dB, the air permeability which is in a trade-off relationship therewith is apt to be easily increased, and there is a possibility that water-proof property is lowered and the collecting efficiency is decreased. On the other hand, when the sound transmission loss exceeds 2.5 dB, in the case of use for water-proof/sound-transmitting protection film, sound transmission is easily inhibited. Further, the air permeability which is in a trade-off relationship therewith is apt to be easily decreased.

In this embodiment, the sound transmission loss can be adjusted to be within the above-mentioned numerical range by adjusting a thickness, a pore size of a pore, a porosity, and the like of the symmetric porous PTFE film to be used according to the expanding conditions and thereafter forming a skin layer by adjusting a temperature, a time and the like in the above-mentioned step (6).

When the skin layer 1131 is formed on the first surface of the asymmetric porous structure 113, a water pressure resistance is 1,000 to 23,000 mmH₂O, preferably 1,000 to 18,000 mmH₂O, and more preferably 1,000 to 16,000 mmH₂O.

When the water pressure resistance is less than 1,000 mmH₂O, there is a fear such that water-proof function of electronic parts, etc. does not work. For example, when a cell phone provided with the asymmetric porous structure of this embodiment is carelessly dropped into water, water may enter into the inside of the housing. As a result, corrosion, deterioration, etc. of built-in parts occur and performance may be impaired. On the other hand, when the water pressure resistance exceeds 23,000 mmH₂O, the air permeability which is in a trade-off relationship therewith is apt to be easily decreased, and the sound transmission loss is apt to be easily increased.

In this embodiment, the water pressure resistance can be adjusted to be within the above-mentioned numerical range by adjusting a thickness, a pore size of a pore, a porosity, and the like of the symmetric porous PTFE film to be used according to the expanding conditions and thereafter forming a skin layer by adjusting a temperature, a time and the like in the above-mentioned step (6).

The water pressure resistance is measured with a low water pressure method in accordance with JIS L 1092 A method. Water pressure is applied on the upper side of the test strip at a constant speed with a water pressure resistance measurement apparatus. Then, the water pressure at which water drops are oozed from three points of the lower side of the test strip is regarded as water pressure resistance.

The collecting efficiency of the asymmetric porous structure 113 according to the water-proof and dust-proof membrane assembly 10 of the present invention is 99.50 to 99.99%, preferably 99.70 to 99.99%, and more preferably 99.90 to 99.99%. In this manner, since the collecting efficiency of the asymmetric porous structure 113 is extremely excellent, the water-proof and dust-proof membrane assembly 10 of the present invention has excellent dust-proof property. The collecting efficiency is calculated by the following formula by setting the porous PTFE film to a filter holder MODEL8130 (manufactured by TSI), regulating an air flow rate on the outlet side to 35.9 L/min with a pressure regulation, filtering the air including colloid particles having a particle size of 0.3 μm, and then measuring the number of permeated particles with a particle measuring machine:

Collecting efficiency (%)=[1−(permeated particle concentration at the downstream side)/(particle concentration in the air at the upstream side)]×100

As described above, the asymmetric porous structure 113 configuring the body of the present invention has heat resistance, flame resistance, acid resistance, alkali resistance, water-proof property, water repellency and oil repellency. Further, combined intersections of the mesh of the asymmetric porous structure 113 exist in all directions. Therefore, the body hardly causes creep.

Furthermore, the asymmetric porous structure 113 of the body 11 can satisfy a water-proof property, dust-proof property, sound transmission capability and air permeability required for individual products, by regulating the pore size and first porosity thereof. For example, when the PTFE film is manufactured by the above expansion forming method, the pore size is controlled by controlling the expanding temperature, expanding speed and the like, and then the first porosity and the uniformity of the asymmetric porous structure are improved by a densifying process.

[Supporting Member]

In the water-proof and dust-proof membrane assembly 10 of the present invention, the supporting member 12 is formed with a polymeric material. Material of the supporting member 12 is not limited specifically, and for example, a polyester resin, a polyethylene resin, an aromatic polyamide resin and the like can be exemplified. The supporting member 12 may be a woven fabric, a nonwoven fabric, a mesh, a net, a sponge form, a foam, a porous body and the like.

Moreover, the supporting member 12 is porous, and the porosity of the supporting member 12 (second porosity) is larger than the first porosity, i.e. 10% to 99.9%. By using such a supporting member, functions such as water-proof property, dust-proof property, sound transmission capability and air permeability are hardly decreased even the body 11 and the supporting member 12 are bonded. Further, supporting strength and water pressure resistance are enhanced by bonding the supporting member 12 to the body 11.

The water-proof and dust-proof membrane assembly 10 of the present invention is obtained by bonding the body 11 and the supporting member 12. Specifically, the first surface 111 of the body 11 and the first contact surface 121 of the supporting member 12 are bonded to each other. The method of bonding between the body 11 and the supporting member 12 is not limited and the bonding can be carried out by using an adhesive, double-faced adhesive tape and the like or by thermocompression bonding or ultrasonic bonding. A preferable bonding method is thermocompression bonding, since the effect of supporting strength and water pressure resistance can be ensured with few loss of the body function.

In the example of FIG. 1, the skin layer 1131 is provided on the first surface 111 side of the body. According to this embodiment, enough air permeability is obtained and thereby formation of dew inside the apparatus can be effectively prevented.

The water-proof and dust-proof membrane assembly of the present invention can be an optional shape, depending on an applied product. For example, the assembly may be circular, elliptical, polygonal, an indeterminate form and the like.

The water-proof and dust-proof membrane assembly 10 of the present invention may be dyed, depending on applied products or a color of applied products. Either the body 11 or the supporting member 12, or both of them may be dyed. The dyeing may be carried out during or after producing the body 11 and the supporting member 12, and the dyeing after bonding the both is also possible. Colors to be dyed are not limited specifically and can be selected appropriately according to applied products or the color of applied products. The method of dyeing can be selected from known methods, and an example thereof is an immersion in a solution in which a dye has been dissolved.

Further, the water-proof and dust-proof membrane assembly 10 of the present invention can undergo an oil repellent process. By conducting an oil repellent process, oil repellency can be improved. For an oil repellent process, known fluorine-containing oil repellent agents or silicone based oil repellent agents can be used. Oil resistance level of the water-proof and dust-proof membrane assembly 10 of the present invention is thereby improved and the water-proof and dust-proof membrane assembly 10 can be used even under a specific operation environment. Either the body 11 or the supporting member 12, or the both of them can undergo the oil repellent process. The oil repellent process may be carried out during or after producing the body 11 and the supporting member 12, and the oil repellent process after bonding the both is also possible. The oil repellent process is carried out by applying and impregnating a known oil repellent agent and the evaluation of oil repellency is conducted according to AATCC188.

The water-proof and dust-proof membrane assembly 10 of the present invention has a Frazier air permeability of 6 to 250 ft³/minft² and preferably 15 to 183 ft³/minft².

The water-proof and dust-proof membrane assembly 10 of the present invention has a Gurley number of 0.25 to 25 seconds, preferably 0.5 to 2.5 seconds, and more preferably 0.6 to 1.0 second under the above conditions.

The water-proof and dust-proof membrane assembly 10 of the present invention has a water pressure resistance of 3,000 to 20,000 mmH₂O, preferably 3,000 to 18,000 mmH₂O, and more preferably 3,000 to 16,000 mmH₂O.

The water-proof and dust-proof membrane assembly 10 of the present invention has a sound transmission loss of 0.7˜3.0 dB, preferably 1.0 to 3.0 dB, and more preferably 1.2 to 3.0 dB.

### Embodiment 2

FIG. 2 shows the water-proof and dust-proof membrane assembly of the embodiment 2 of the present invention. Reference numerals of FIG. 2 are the same as those of FIG. 1. The water-proof and dust-proof membrane assembly 10 of an example of FIG. 2 is the same as the water-proof and dust-proof membrane assembly of the embodiment 1, except that the skin layer 1131 is provided at the second surface 112 side differently from the water-proof and dust-proof membrane assembly of FIG. 1 where the skin layer 1131 is provided on the first surface 111 side.

In the water-proof and dust-proof membrane assembly 10 of an example of FIG. 2, the skin layer 1131 is provided at the second surface 112 side of the body 11. As a result, when the same body 11 is used, air permeation is decreased more than the embodiment 1 while water pressure resistance and sound transmission loss increase more than the embodiment 1. The water-proof and dust-proof membrane assembly 10 of an example of FIG. 2 is therefore preferably used underwater, for example, for an underwater camera. In addition, by modifying the configuration of the body, air permeability and the like can be improved. For this reason, the water-proof and dust-proof membrane assembly of an example of FIG. 2 has the same functions as those of the water-proof and dust-proof membrane assembly of an example of FIG. 1. In the water-proof and dust-proof membrane assembly 10 of an example of FIG. 2, the value of air permeation, water pressure resistance and sound transmission loss is also within the range described in the above embodiment 1.

### Embodiment 3

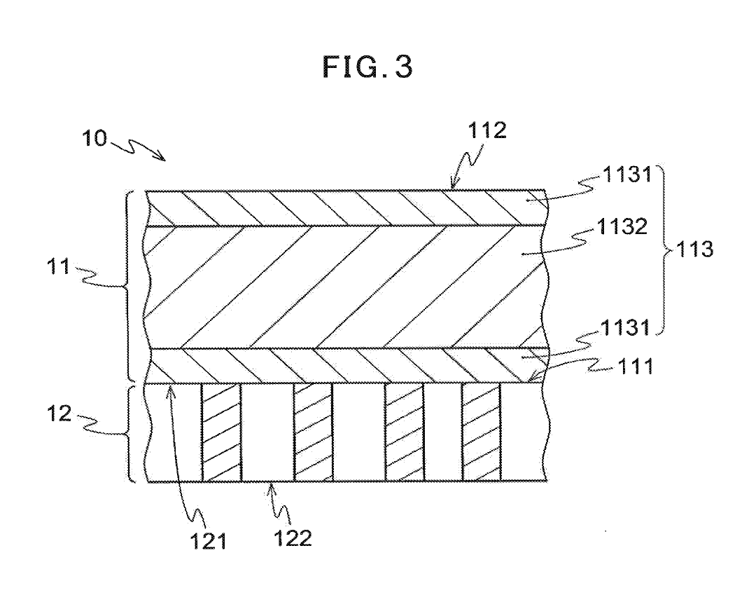

FIG. 3 shows the water-proof and dust-proof membrane assembly of the embodiment 3 of the present invention. Reference numerals of FIG. 3 are the same as those of FIG. 1. The water-proof and dust-proof membrane assembly of an example of FIG. 3 is the same as the water-proof and dust-proof membrane assembly of the embodiment 1, except that the skin layers 1131 are provided on both of the first surface 111 side and the second surface 112 side.

With the configuration of FIG. 3, water pressure resistance can be improved, and the other functions and effects thereof are the same as those of FIG. 1. This is because the pore size of the body composing the water-proof and dust-proof membrane assembly of the present invention is far greater than a size of the air molecules (up to 0.0004 μm). Moreover, since the skin layer 1131 is also provided at the second surface 112 side, water pressure resistance can be improved similarly to the embodiment 2.

The asymmetric porous structure 113 used in the embodiment 3 has a Frazier air permeability of 8.0 to 250 ft³/minft² and preferably 15 to 250 ft³/minft².

The asymmetric porous structure 113 used in the embodiment 3 has a Gurley number of 0.3 to 25 seconds, preferably 0.5 to 2.5 seconds, and more preferably 0.6 to 1.0 second.

The asymmetric porous structure 113 used in the embodiment 3 has a water pressure resistance of 1,000 to 23,000 mmH₂O, preferably 1,100 to 23,000 mmH₂O, and more preferably 1,200 to 23,000 mmH₂O.

The asymmetric porous structure 113 used in the embodiment 3 has a sound transmission loss of 0.5 to 2.0 dB, preferably 0.5 to 1.8 dB, and more preferably 0.5 to 1.3 dB.

The water-proof and dust-proof membrane assembly 10 of this embodiment has a Frazier air permeability of 12.6 to 250 ft³/minft² and preferably 12.6 to 220 ft³/minft².

The water-proof and dust-proof membrane assembly 10 of this embodiment has a Gurley number of 0.3 to 25 seconds, preferably 0.5 to 2.5 seconds, and more preferably 0.6 to 1.0 second under the above conditions.

The water-proof and dust-proof membrane assembly 10 of this embodiment has a water pressure resistance of 13,000 to 25,000 mmH₂O, preferably 14,000 to 25,000 mmH₂O, and more preferably 14,000 to 20,000 mmH₂O.

The water-proof and dust-proof membrane assembly 10 of this embodiment has a sound transmission loss of 0.7˜3.0 dB, preferably 0.7 to 2.5 dB, and more preferably 0.7 to 1.0 dB.

Therefore the asymmetric porous structure in the form of membrane that is the body can be changed according to a demand for water pressure resistance of a product using the water-proof and dust-proof membrane assembly of the present invention.

The skin layer 1131 may be formed on the both sides of the first surface 111 and the second surface 112 of the porous layer 1132 by the following method.

First of all, the original PTFE film 13 obtained from the aforementioned processes (1) to (3) expanded in the machine direction (MD). It is preferable that the expanding ratio is 3 to 30, preferably 5 to 20 and more preferably 10 to 50, and that the expanding temperature is 200 to 400° C., preferably 250 to 350° C. and more preferably 280 to 330° C. Here, the expanding ratio of 3 means that a porous structure having the length of 1 is expanded threefold (1:3).

Then the porous structure 13 which underwent the expanding in the machine direction (MD) is expanded in the transverse direction (TD). It is preferable that the expanding ratio is 2 to 20, preferably 3 to 15 and more preferably 3 to 12, and that the expanding temperature is 200 to 400° C., preferably 250 to 350° C. and more preferably 280 to 330° C.

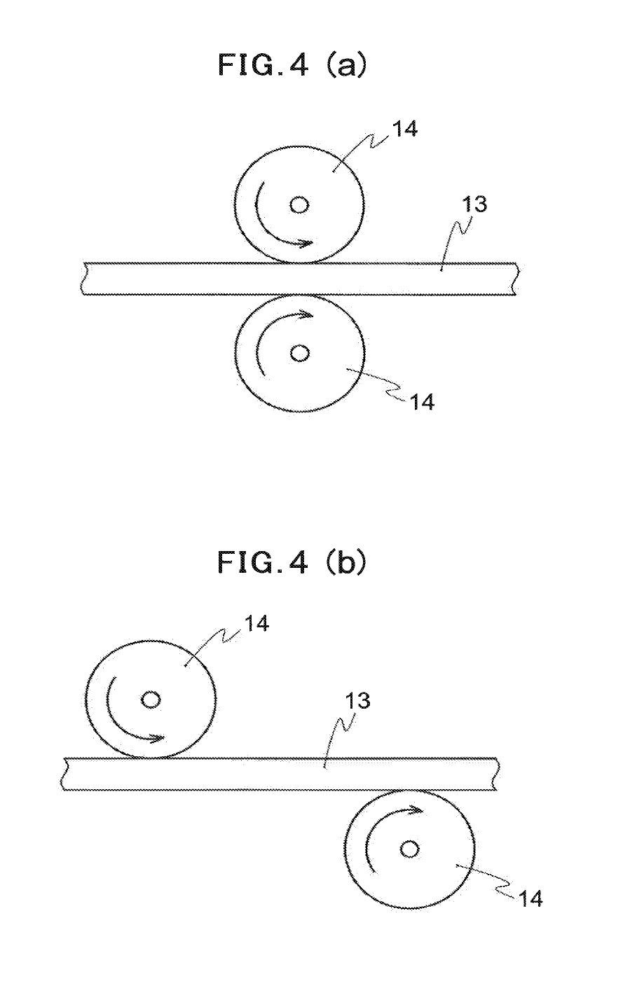

The uniform symmetric porous structure 13 is firstly heated and densified using heated rollers 14 to form a skin layer 1131. The heating process is, as shown in FIG. 4 (a), conducted by sandwiching the uniform symmetric porous structure 13 with heating rollers from above and below, and moving the rollers in the same direction. Alternatively, as shown in FIG. 4 (b), it is also possible to treat one surface of the uniform symmetric porous structure 13 with the heated roller 14 to densify it and then treat the other surface with another heated roller 14 to densify it. In addition, when treating the both surfaces of the uniform symmetric porous structure 13 separately with a heated roller, the method is not limited to the example of FIG. 4 (b) and it is also possible to conduct a heat treatment with one heated roller 14, by changing the direction of movement of the film with the roller or the like. In this manner, the skin layer 1131 is formed by heating. The temperature of the heated rollers 14 is, for example, 100 to 400° C. When the heating process is conducted by sandwiching the uniform symmetric porous structure 13 with heating rollers from above and below, low temperature (for example, 250 to 300° C.) is preferable and when the skin layer 1131 is formed by heating above and below thereof separately, high temperature (for example, 350 to 400° C.) is preferable. It is more preferable to form a skin layer 1131 by hating above and below separately, since the film is hardly affected by pressurization of a roller.

Then, the heated and densified expanded porous PTFE film undergoes a second expanding process in a transverse direction. In the second expanding in a transverse direction (TD), it is preferable that the expanding ratio is 1.5 to 10, preferably 2 to 6 and more preferably 3 to 6, and that the expanding temperature is 200 to 400° C., preferably 250 to 350° C. and more preferably 280 to 330° C.

After the expanding process, a heating process using heated rollers 14 is further conducted. The temperature of the heated rollers 14 is, for example, 100 to 400° C., and the method of the heating process is similar to that described above.

Here, the second expanding in a transverse direction and the heating process thereafter can be omitted.

As described above, the water-proof and dust-proof membrane assembly 10 of the present invention is excellent in water-proof property, dust-proof property, air permeability and water pressure resistance. Therefore the water-proof and dust-proof membrane assembly 10 of the present invention can be widely used in general electronic products, underwater electronic products and other products.

Examples of a general electronic product are digital camera, cell phone, MP3 player, earphone, microphone, speaker, radio, digital book, automobile backup radar, transceiver, projector, ink cartridge, battery box, outdoor lighting equipment, automobile lamp, LED lighting device, gas detector, medical electronic product, military-specific electronic product and the like.

Examples of an underwater electronic product are products where relatively high water-proof standards are required, such as underwater digital video camera, underwater digital camera, underwater MP3 player, underwater lighting apparatus, water-proof adapter and the like.

Moreover, the water-proof and dust-proof membrane assembly 10 of the present invention can be also applied to a water-proof and dust-proof vented container requiring a specific condition or other products such as can packaging container (for example, Petri dish, solar cell junction box and container etc.).

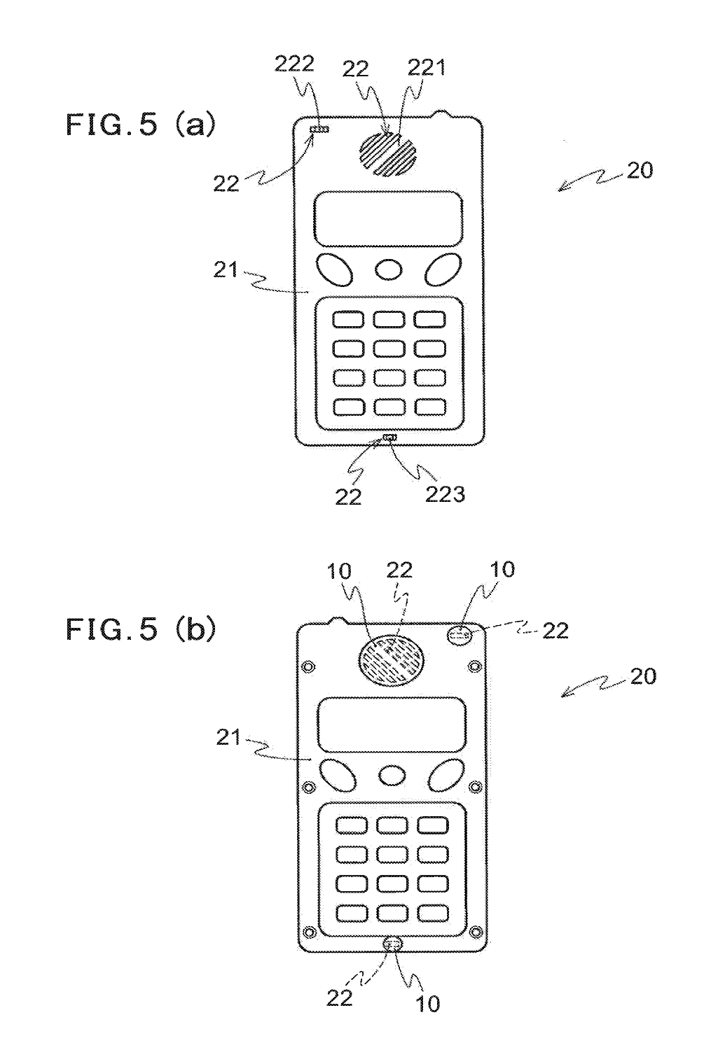

FIG. 5 is a schematic view of a cell phone using the water-proof and dust-proof membrane assembly 10 of the present invention. As shown in FIG. 5 (a), the cell phone 20 has a housing 21 and at least one electronic circuit component (not shown). In the front surface of the housing, at least one opening 22 (three openings in the example of this figure) is provided. Each opening 22 is provided with a transceiver 221, a speaker 222 and a microphone 223. Further, FIG. 5 (b) is a view showing the inside of the housing 21 of the cell phone shown in FIG. 5 (a). As shown in FIG. 5 (b), the water-proof and dust-proof membrane assembly 10 of the present invention is located at each opening 22 by being fitted. In this manner, it is possible to prevent moisture, salt content or other liquid from intruding into a product via the openings 22, by locating the water-proof and dust-proof membrane assembly 10 fitted for the openings 22. As a result, the electronic circuit component inside the housing can be protected and thereby the service life of cell phone can be improved. The similar effect can be exhibited also in other electronic devices.

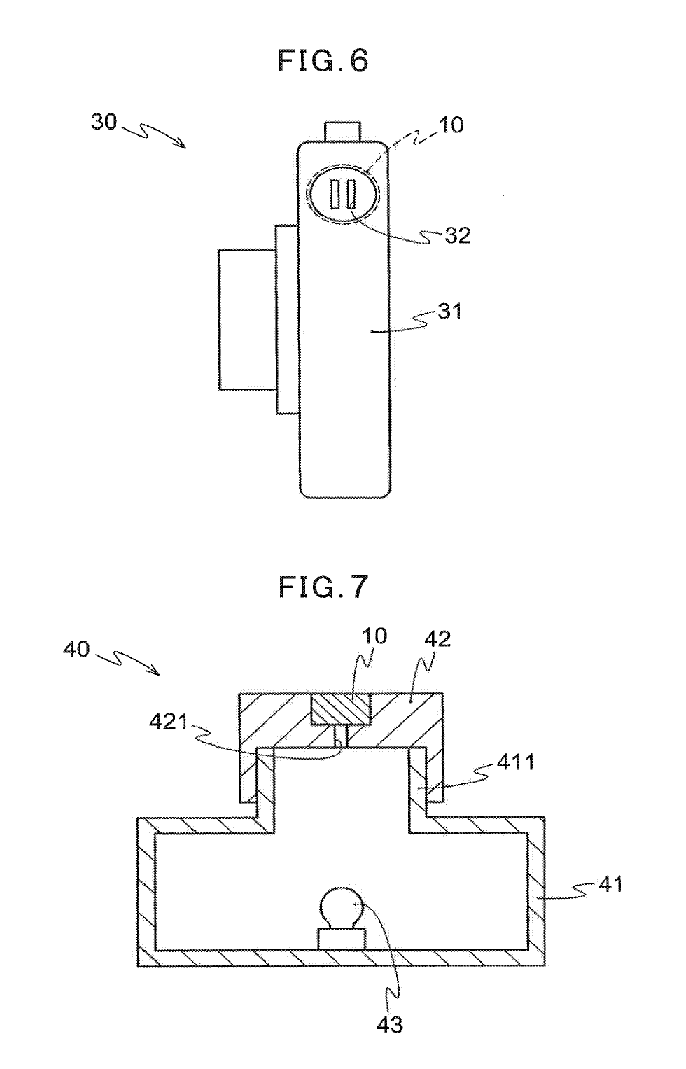

FIG. 6 is a schematic view of an underwater digital camera 30 using the water-proof and dust-proof membrane assembly 10 of the present invention. As shown in FIG. 6, the underwater digital camera 30 has a housing 31 and at least one electronic circuit component (not shown). In the front surface of the housing 31, at least one opening 32 (one opening in the example of this figure) is provided. This opening 32 is used as a sound transmitter or a microphone at video recording. For the underwater digital camera 30, quality of sound transmitted at video recording is as important as the water-proof function. In the example of FIG. 6, the water-proof and dust-proof membrane assembly 10 of the present invention which is fitted for the opening 32 is located in the housing. In this manner, it is possible to prevent liquid such as water from intruding into a product via the openings 32, by locating the water-proof and dust-proof membrane assembly 10 fitted for the openings 32. On the other hand, the water-proof and dust-proof membrane assembly 10 of the present invention is excellent in sound transmitting capability and water pressure resistance. As a result, the electronic circuit component inside the housing can be protected even if the camera is used underwater and thereby the service life of the underwater digital camera can be improved while its sound transmitting capability is excellent.

FIG. 7 is a schematic view of a lighting system using the water-proof and dust-proof membrane assembly 10 of the present invention. As shown in FIG. 7, the lighting system 40 has a hollow housing 41, a cover 42 and at least one light source device (for example, light emitting diode) 43. The hollow housing 41 has a window portion 411 which mates with the cover 42. The cover 42 has at least one opening 421. The at least one light source device 43 is located inside the housing 41, being fitted for the at least one opening 421. The water-proof and dust-proof membrane assembly 10 of the present invention is located over the at least one opening 421. Since the water-proof and dust-proof membrane assembly 10 of the present invention has excellent water-proof property, dust-proof property and air permeability, moisture has free access to inside the lighting system 40 via the opening 421 of the cover 42. As a result, dew inside the hollow housing 41 of the lighting system can be rapidly removed and reduced. At the same time, intrusion of exterior dust or rain water into the system can be prevented.

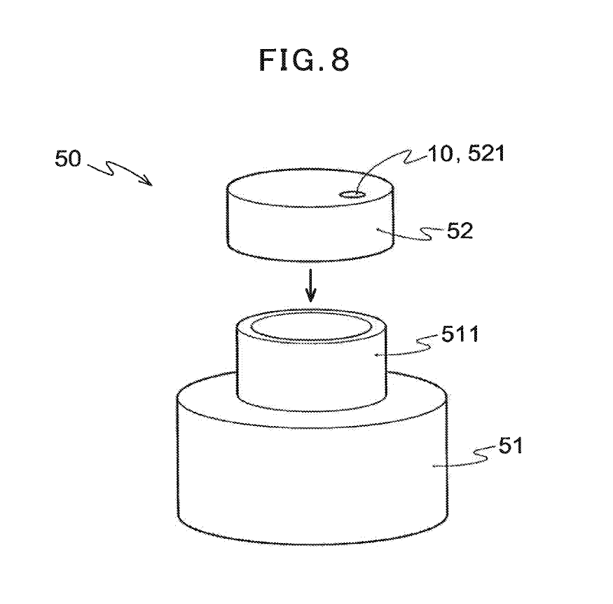

FIG. 8 is a schematic view of a container using the water-proof and dust-proof membrane assembly 10 of the present invention. As shown in FIG. 8, the container 50 has a hollow housing 51 and a cap 52. The hollow housing 51 has a window portion 511 which mates with the cap 52. The cap 52 has at least one opening 521. The water-proof and dust-proof membrane assembly 10 of the present invention is located over the opening 521 provided in the cap 52. Since the water-proof and dust-proof membrane assembly 10 of the present invention has excellent water-proof property, dust-proof property and air permeability, moisture has free access to inside the cap 50 via the opening 521 of the cap 52. As a result, dew inside the hollow housing 51 of the container 50 can be rapidly removed and reduced, and thereby the inside of the container 50 can be protected from moisture.

Hereinafter, the present invention will be explained based on Examples, but the present invention is not limited thereto.

### EXAMPLES

### Example-1

### Example A

The water-proof and dust-proof membrane assembly 10 of the present invention in which the skin layer 1131 is provided on the first surface 111 side of the body 11 as shown in FIG. 1 was used.

More specifically, a PTFE fine powder obtained by emulsion polymerization (Polyflon F-104 available from Daikin Industries, Ltd.) and naphtha were mixed in a ratio of 80/20 (mass ratio), and an obtained mixture was subjected to extrusion with a paste extruder to obtain a cylindrical extrudate having a diameter of 17 mm. R.R of an extrusion die and an angle of the die were set to be 80:1 and 60°, respectively. Then, the obtained extrudate was fed through a pair of metal rolls having a diameter of 500 mm to be rolled to form a sheet-like product. After the rolling, the naphtha was removed at 260° C. to obtain a PTFE sheet of about 250 m long×about 0.2 mm thick×about 125 mm wide. The obtained sheet was heated to 300° C., and then subjected to stretching at 280° C. at a stretch ratio of 20 in a longitudinal axis direction (MD direction) and subsequently stretching at 280° C. at a stretch ratio of 5 in a lateral axis direction (TD direction).

A symmetrical porous PTFE film having a porosity of 90%, a thickness of 10 μm, and a pore size of 0.7 to 1.6 μm was produced in a manner as mentioned above. This symmetrical porous PTFE film was subjected to heat treatment for heat setting for 6 to 10 seconds at 340° C. which is a little bit higher than the melting point (about 327° C.) of PTFE and lower than the decomposition temperature thereof. While cooling one surface of the symmetrical porous PTFE film at −10° C. after the heat setting, another surface was heat-treated and thereafter cooled to continuously produce an asymmetrical porous PTFE film. The heat treatment was performed under the condition of heat-treating one surface of the symmetrical porous PTFE film at 340° C. for 1 to 5 seconds. In this manner, the asymmetrical porous PTFE film having a porosity of 89%, a thickness of 10 μm, and a pore size of 0.09 to 1.4 μm was obtained.

Then a surface of the supporting member was laid on the surface of the skin layer of the obtained asymmetrical porous PTFE film, and the both were fed through a pair of metal rolls, thereby being heated and pressed to be laminated with each other. The supporting member used was a non-woven PET fabric, and a melting point and a porosity of this non-woven fabric were about 260° C. and 90% or more, respectively. A contact pressure of the metal rolls was 150 psi, the pair of metal rolls is capable of heating up to the melting point of the supporting member, and a pressing time was set to be 0.5 second for lamination. By the above-mentioned steps, a sample of Example A as shown in FIG. 1 was produced.

### Example B

The water-proof and dust-proof membrane assembly of the present invention in which the skin layer 1131 is provided on the second surface 112 side of the body 11 as shown in FIG. 2 was used.

More specifically, in Example B, too, an asymmetrical porous PTFE film was produced in the same manner as in Example A. A surface of the supporting member was laid on the surface of the continuous porous layer (a surface opposite to the skin layer surface), and this was passed through the pair of metal rolls to laminate the continuous porous surface of the asymmetrical porous PTFE film with the supporting member. In this case, the same PET non-woven fabric as in Example A was used as the supporting member, and the lamination of the both with a pair of metal rolls were also performed under the same conditions as in Example A. By the above-mentioned steps, a sample of Example B as shown in FIG. 2 was produced.

Gurley number, Frazier air permeability, water pressure resistance and sound transmission loss of the above Examples A and B were examined and the results are shown in the following Table. The following value is the average value of the measurements of 10 assemblies.

TABLE 1

| | Example A | Example B |
|---|---|---|
| Gurley number | 0.25 to 0.28 | 14.7 to 15.2 |
| (second/100 ml) | | |
| Frazier air | 129 to 135 | 8.1 to 8.7 |
| permeability | | |
| (ft³/minft²) | | |
| Water pressure | 2,600 to 2,800 | 10,500 to 11,500 |
| resistance (mmH₂O) | | |
| Sound transmission | less than 2.5 | less than 1.0 |
| loss (dB) | | |

From this Table, it is noticed that when the same asymmetric porous structure is used, the one having the skin layer on the first surface side has smaller Gurley number and larger air permeability. Therefore it is notified that the structure of embodiment 1 is more preferable when used for preventing dew formation of non-electronic components.

On the other hand, it is noticed that the one having the skin layer on the second surface side has smaller air permeability while having larger water pressure resistance and smaller sound transmission loss. Therefore it is noticed that the structure of embodiment 2 is more preferable when used for preventing dew formation of normal consumer electronic products components and more suitable for underwater electronic devices and the like.

### Example 2-1

One surface of a symmetric porous structure having a porosity of 60%, a thickness of 20 to 25 μm and a pore size of 0.20 to 0.45 μm was cooled while the other surface was heated as shown in the following Table. The results are shown in Table 2.

TABLE 2

| | Heat treatment temperature (° C.) | | | | | |
|---|---|---|---|---|---|---|
| | unheated | 260 | 300 | 340 | 380 | 400 |
| Thickness of | 20 | 21 | 23 | 20 | 23 | 16 |
| film (μm) | | | | | | |
| Porosity (%) | 60 | 60 | 62 | 63 | 61 | 48 |
| Pore size (μm) | 0.20 to | 0.16 to | 0.11 to | 0.04 to | 0.03 to | 0.03 to |
| | 0.45 | 0.45 | 0.45 | 0.45 | 0.45 | 0.25 |
| Water contact | 117 | 118 | 130 | 133 | 129 | 113 |
| angle (°) | | | | | | |
| Frazier air | 15.1 | 17.5 | 21.1 | 24.5 | 22.9 | 7.4 |
| permeability | | | | | | |
| (ft³/minft²) | | | | | | |
| Frazier air | 1 | 1.159 | 1.397 | 1.623 | 1.516 | 0.49 |
| permeability | | | | | | |
| index | | | | | | |
| Collecting | 99.21 | 99.64 | 99.92 | 99.99 | 99.99 | 99.99 |
| efficiency (%) | | | | | | |
| Water | 7,000 | 9,000 | >10,000 | >10,000 | >15,000 | >15,000 |
| pressure | | | | | | |
| resistance | | | | | | |
| (mmH₂O) | | | | | | |
| Gurley | 6.6 | 6.5 | 6.3 | 6.1 | 6.4 | 27.3 |
| number | | | | | | |
| (second) | | | | | | |
| Sound | 1.2 | 1.2 | 1.3 | 1.5 | 1.7 | 1.9 |
| transmission | | | | | | |
| loss (dB) | | | | | | |

From Table 2, it is noticed that the asymmetric porous structure which is excellent in water-proof property, dust-proof property, sound transmission capability and air permeability can be obtained when heated at especially 300 to 380° C.

### Example 2-2

One surface of a symmetric porous structure having a porosity of 70%, a thickness of 20 to 25 μm and a pore size of 0.20 to 0.45 μm was cooled while the other surface was heated as shown in the following Table. The results are shown in Table 3.

TABLE 3

| | Heat treatment temperature (° C.) | | | | | |
|---|---|---|---|---|---|---|
| | Unheated | 260 | 300 | 340 | 380 | 400 |
| Thickness of | 21 | 21 | 21 | 22 | 21 | 18 |
| film (μm) | | | | | | |
| Porosity (%) | 70 | 70 | 71 | 72 | 70 | 59 |
| Pore size (μm) | 0.21 to | 0.19 to | 0.10 to | 0.03 to | 0.03 to | 0.03 to |
| | 0.45 | 0.45 | 0.45 | 0.45 | 0.45 | 0.27 |
| Water contact | 116 | 120 | 127 | 130 | 129 | 115 |
| angle (°) | | | | | | |
| Frazier air | 17.2 | 18.6 | 24.5 | 30.5 | 27.1 | 8.1 |
| permeability | | | | | | |
| (ft³/minft²) | | | | | | |
| Frazier air | 1 | 1.081 | 1.424 | 1.773 | 1.575 | 0.47 |
| permeability | | | | | | |
| index | | | | | | |
| Collecting | 99.28 | 99.59 | 99.94 | 99.99 | 99.99 | 99.99 |
| efficiency (%) | | | | | | |
| Water | 6,500 | 8,600 | >10,000 | >10,000 | >15,000 | >15,000 |
| pressure | | | | | | |
| resistance | | | | | | |
| (mmH₂O) | | | | | | |
| Gurley | 5.9 | 5.6 | 5.3 | 5.1 | 5.6 | 26.4 |
| number | | | | | | |
| (second) | | | | | | |
| Sound | 1.1 | 1.1 | 1.2 | 1.3 | 1.6 | 1.9 |
| transmission | | | | | | |
| loss (dB) | | | | | | |

From Table 3, it is noticed that the asymmetric porous structure which is excellent in water-proof property, dust-proof property, sound transmission capability and air permeability can be obtained when heated at especially 300 to 380° C.

### Example 2-3

One surface of a symmetric porous structure having a porosity of 80%, a thickness of 20 to 25 μm and a pore size of 0.20 to 0.45 μm was cooled while the other surface was heated as shown in the following Table. The results are shown in Table 4.

TABLE 4

| | Heat treatment temperature (° C.) | | | | | |
|---|---|---|---|---|---|---|
| | Unheated | 260 | 300 | 340 | 380 | 400 |
| Thickness of | 22 | 21 | 21 | 20 | 23 | 15 |
| film (μm) | | | | | | |
| Porosity (%) | 81 | 80 | 80 | 82 | 79 | 71 |
| Pore size (μm) | 0.20 to | 0.19 to | 0.09 to | 0.03 to | 0.03 to | 0.02 to |
| | 0.45 | 0.45 | 0.45 | 0.45 | 0.45 | 0.28 |
| Water contact | 118 | 122 | 129 | 131 | 132 | 116 |
| angle (°) | | | | | | |
| Frazier air | 17.3 | 19.2 | 27.6 | 32.5 | 31.1 | 7.8 |
| permeability | | | | | | |
| (ft³/minft²) | | | | | | |
| Frazier air | 1 | 1.109 | 1.595 | 1.878 | 1.797 | 0.45 |
| permeability | | | | | | |
| index | | | | | | |
| Collecting | 99.35 | 99.61 | 99.97 | 99.99 | 99.99 | 99.99 |
| efficiency (%) | | | | | | |
| Water | 6,000 | 8,400 | >10,000 | >10,000 | >15,000 | >15,000 |
| pressure | | | | | | |
| resistance | | | | | | |
| (mmH₂O) | | | | | | |
| Gurley | 4.9 | 4.8 | 4.7 | 4.2 | 4.8 | 24.9 |
| number | | | | | | |
| (second) | | | | | | |
| Sound | 1 | 1 | 1.1 | 1.1 | 1.5 | 1.9 |
| transmission | | | | | | |
| loss (dB) | | | | | | |

From Table 4, it is noticed that the asymmetric porous structure which is excellent in water-proof property, dust-proof property, sound transmission capability and air permeability can be obtained when heated at 260 to 380° C., especially 300 to 380° C.

### Example 2-4

One surface of a symmetric porous structure having a porosity of 90%, a thickness of 20 to 25 μm and a pore size of 0.20 to 0.45 μm was cooled while the other surface was heated as shown in the following Table. The results are shown in Table 5.

TABLE 5

| | Heat treatment temperature (° C.) | | | | | |
|---|---|---|---|---|---|---|
| | Unheated | 260 | 300 | 340 | 380 | 400 |
| Thickness of | 22 | 23 | 20 | 19 | 22 | 16 |
| film (μm) | | | | | | |
| Porosity (%) | 86 | 86 | 86 | 87 | 86 | 75 |
| Pore size (μm) | 0.20 to | 0.17 to | 0.08 to | 0.03 to | 0.03 to | 0.02 to |
| | 0.45 | 0.45 | 0.45 | 0.45 | 0.45 | 0.29 |
| Water contact | 119 | 122 | 131 | 135 | 132 | 117 |
| angle (°) | | | | | | |
| Frazier air | 19.5 | 21.1 | 30.5 | 34.5 | 32.8 | 8.6 |
| permeability | | | | | | |
| (ft³/minft²) | | | | | | |
| Frazier air | 1 | 1.082 | 1.564 | 1.769 | 1.682 | 0.441 |
| permeability | | | | | | |
| index | | | | | | |
| Collecting | 99.51 | 99.89 | 99.98 | 99.99 | 99.99 | 99.99 |
| efficiency (%) | | | | | | |
| Water | 5,500 | 8,500 | >10,000 | >10,000 | >15,000 | >15,000 |
| pressure | | | | | | |
| resistance | | | | | | |
| (mmH₂O) | | | | | | |
| Gurley | 3.9 | 3.8 | 3.2 | 2.9 | 3.5 | 23.1 |
| number | | | | | | |
| (second) | | | | | | |
| Sound | 0.8 | 0.9 | 1 | 1 | 1.3 | 1.8 |
| transmission | | | | | | |
| loss (dB) | | | | | | |

From Table 5, it is noticed that the asymmetric porous structure which is excellent in water-proof property, dust-proof property, sound transmission capability and air permeability can be obtained when heated at 260 to 380° C., especially 300 to 340° C.

### Example 2-5

One surface of a symmetric porous structure having a porosity of 60%, a thickness of 10 μm or less and a pore size of 0.7 to 1.3 μm was cooled while the other surface was heated as shown in the following Table. The results are shown in Table 6.

TABLE 6

| | Heat treatment temperature (° C.) | | | | | |
|---|---|---|---|---|---|---|
| | Unheated | 260 | 300 | 340 | 380 | 400 |
| Thickness of | 10 | 9 | 10 | 9 | 8 | 8 |
| film (μm) | | | | | | |
| Porosity (%) | 60 | 60 | 62 | 63 | 61 | 48 |
| Pore size (μm) | 0.70 to | 0.31 to | 0.13 to | 0.09 to | 0.08 to | 0.06 to |
| | 1.3 | 1.3 | 1.3 | 1.2 | 0.68 | 0.31 |
| Water contact | 110 | 115 | 121 | 129 | 127 | 114 |
| angle (°) | | | | | | |
| Frazier air | 27.5 | 30.9 | 37.3 | 43.2 | 35.8 | 11.9 |
| permeability | | | | | | |
| (ft³/minft²) | | | | | | |
| Frazier air | 1 | 1.123 | 1.356 | 1.57 | 1.301 | 0.432 |
| permeability | | | | | | |
| index | | | | | | |
| Collecting | 99.29 | 99.88 | 99.97 | 99.99 | 99.99 | 99.99 |
| efficiency (%) | | | | | | |
| Water | 3,500 | 6,000 | 8,600 | >10,000 | >10,000 | >10,000 |
| pressure | | | | | | |
| resistance | | | | | | |
| (mmH₂O) | | | | | | |
| Gurley | 1 | 1 | 0.9 | 0.8 | 1 | 16.9 |
| number | | | | | | |
| (second) | | | | | | |
| Sound | 0.6 | 0.6 | 0.6 | 0.6 | 0.7 | 1.4 |
| transmission | | | | | | |
| loss (dB) | | | | | | |

From Table 6, it is noticed that the asymmetric porous structure which is excellent in water-proof property, dust-proof property, sound transmission capability and air permeability can be obtained when heated at 260 to 380° C., especially 300 to 380° C.

### Example 2-6

One surface of a symmetric porous structure having a porosity of 70%, a thickness of 10 μm or less and a pore size of 0.7 to 1.3 μm was cooled while the other surface was heated as shown in the following Table. The results are shown in Table 7.

TABLE 7

| | Heat treatment temperature (° C.) | | | | | |
|---|---|---|---|---|---|---|
| | Unheated | 260 | 300 | 340 | 380 | 400 |
| Thickness of | 11 | 9 | 9 | 9 | 8 | 8 |
| film (μm) | | | | | | |
| Porosity (%) | 71 | 71 | 73 | 71 | 72 | 71 |
| Pore size (μm) | 0.70 to | 0.32 to | 0.12 to | 0.09 to | 0.08 to | 0.05 to |
| | 1.3 | 1.3 | 1.3 | 1.2 | 0.99 | 0.35 |
| Water contact | 113 | 120 | 124 | 129 | 124 | 114 |
| angle (°) | | | | | | |
| Frazier air | 29.1 | 32.8 | 39.3 | 46.8 | 37.1 | 12.5 |
| permeability | | | | | | |
| (ft³/minft²) | | | | | | |
| Frazier air | 1 | 1.127 | 1.35 | 1.608 | 1.274 | 0.429 |
| permeability | | | | | | |
| index | | | | | | |
| Collecting | 99.31 | 99.79 | 99.98 | 99.99 | 99.99 | 99.99 |
| efficiency (%) | | | | | | |
| Water | 2,500 | 5,800 | 8,500 | >10,000 | >10,000 | >10,000 |
| pressure | | | | | | |
| resistance | | | | | | |
| (mmH₂O) | | | | | | |
| Gurley | 0.9 | 0.9 | 0.8 | 0.6 | 0.9 | 15.6 |
| number | | | | | | |
| (second) | | | | | | |
| Sound | 0.6 | 0.6 | 0.6 | 0.6 | 0.7 | 1.3 |
| transmission | | | | | | |
| loss (dB) | | | | | | |

From Table 7, it is noticed that the asymmetric porous structure which is excellent in water-proof property, dust-proof property, sound transmission capability and air permeability can be obtained when heated at 260 to 380° C., especially 300 to 380° C.

### Example 2-7

One surface of a symmetric porous structure having a porosity of 80%, a thickness of 10 μm or less and a pore size of 0.7 to 1.3 μm was cooled while the other surface was heated as shown in the following Table. The results are shown in Table 8.

TABLE 8

| | Heat treatment temperature (° C.) | | | | | |
|---|---|---|---|---|---|---|
| | Unheated | 260 | 300 | 340 | 380 | 400 |
| Thickness of | 10 | 9 | 10 | 10 | 9 | 8 |
| film (μm) | | | | | | |
| Porosity (%) | 80 | 83 | 82 | 83 | 81 | 82 |
| Pore size (μm) | 0.71 to | 0.31 to | 0.11 to | 0.09 to | 0.09 to | 0.05 to |
| | 1.3 | 1.3 | 1.3 | 1.3 | 0.91 | 0.37 |
| Water contact | 114 | 121 | 125 | 130 | 126 | 116 |
| angle (°) | | | | | | |
| Frazier air | 31.2 | 35.1 | 42.6 | 48.9 | 38.7 | 13.4 |
| permeability | | | | | | |
| (ft³/minft²) | | | | | | |
| Frazier air | 1 | 1.125 | 1.365 | 1.567 | 1.24 | 0.429 |
| permeability | | | | | | |
| index | | | | | | |
| Collecting | 99.35 | 99.81 | 99.98 | 99.99 | 99.99 | 99.99 |
| efficiency (%) | | | | | | |
| Water | 1,500 | 5,500 | 8,400 | >10,000 | >10,000 | >10,000 |
| pressure | | | | | | |
| resistance | | | | | | |
| (mmH₂O) | | | | | | |
| Gurley | 0.7 | 0.7 | 0.6 | 0.5 | 0.7 | 14.4 |
| number | | | | | | |
| (second) | | | | | | |
| Sound | 0.5 | 0.5 | 0.5 | 0.5 | 0.6 | 1.2 |
| transmission | | | | | | |
| loss (dB) | | | | | | |

From Table 8, it is noticed that the asymmetric porous structure which is excellent in water-proof property, dust-proof property, sound transmission capability and air permeability can be obtained when heated at 260 to 380° C., especially 340 to 380° C.

### Example 2-8

One surface of a symmetric porous structure having a porosity of 90%, a thickness of 10 μm or less and a pore size of 0.7 to 1.3 μm was cooled while the other surface was heated as shown in the following Table. The results are shown in Table 9.

TABLE 9

| | Heat treatment temperature (° C.) | | | | | |
|---|---|---|---|---|---|---|
| | Unheated | 260 | 300 | 340 | 380 | 400 |
| Thickness of | 11 | 10 | 10 | 9 | 8 | 8 |
| film (μm) | | | | | | |
| Porosity (%) | 90 | 92 | 90 | 91 | 89 | 91 |
| Pore size (μm) | 0.72 to | 0.32 to | 0.12 to | 0.09 to | 0.09 to | 0.05 to |
| | 1.3 | 1.3 | 1.3 | 1.3 | 0.98 | 0.35 |
| Water contact | 111 | 118 | 128 | 131 | 129 | 117 |
| angle (°) | | | | | | |
| Frazier air | 33.1 | 38.4 | 45.3 | 51.9 | 40.9 | 15.7 |
| permeability | | | | | | |
| (ft³/minft²) | | | | | | |
| Frazier air | 1 | 1.16 | 1.368 | 1.567 | 1.235 | 0.474 |
| permeability | | | | | | |
| index | | | | | | |
| Collecting | 99.49 | 99.88 | 99.98 | 99.99 | 99.99 | 99.99 |
| efficiency (%) | | | | | | |
| Water | 1,000 | 5,600 | 8,300 | >10,000 | >10,000 | >10,000 |
| pressure | | | | | | |
| resistance | | | | | | |
| (mmH₂O) | | | | | | |
| Gurley | 0.5 | 0.5 | 0.4 | 0.3 | 0.4 | 13.7 |
| number | | | | | | |
| (second) | | | | | | |
| Sound | 0.5 | 0.5 | 0.5 | 0.5 | 0.6 | 1.1 |
| transmission | | | | | | |
| loss (dB) | | | | | | |

From Table 9, it is noticed that the asymmetric porous structure which is excellent in water-proof property, dust-proof property, sound transmission capability and air permeability can be obtained when heated at 260 to 380° C., especially 340 to 380° C.

### Comparative Example 2-1

One surface of a symmetric porous structure having a porosity of 60%, a thickness of 50 μm and a pore size of 0.05 to 0.08 μm was cooled while the other surface was heated as shown in the following Table. The results are shown in Table 10.

TABLE 10

| | Heat treatment temperature (° C.) | | | | | |
|---|---|---|---|---|---|---|
| | Unheated | 260 | 300 | 340 | 380 | 400 |
| Thickness of | 50 | 50 | 52 | 53 | 52 | 38 |
| film (μm) | | | | | | |
| Porosity (%) | 60 | 61 | 62 | 64 | 63 | 39 |
| Pore size (μm) | 0.05 to | 0.05 to | 0.03 to | 0.02 to | 0.01 to | 0.01 to |
| | 0.08 | 0.08 | 0.08 | 0.08 | 0.08 | 0.04 |
| Water contact | 117 | 118 | 125 | 129 | 128 | 113 |
| angle (°) | | | | | | |
| Frazier air | 9.8 | 10.5 | 8.9 | 9.5 | 10.1 | 6.2 |
| permeability | | | | | | |
| (ft³/minft²) | | | | | | |
| Frazier air | 1 | 1.071 | 0.908 | 0.969 | 1.031 | 0.633 |
| permeability | | | | | | |
| index | | | | | | |
| Collecting | 99.19 | 99.68 | 99.98 | 99.99 | 99.99 | 99.99 |
| efficiency (%) | | | | | | |
| Water | 7500 | 9500 | >10000 | >10000 | >15000 | >15000 |
| pressure | | | | | | |
| resistance | | | | | | |
| (mmH₂O) | | | | | | |

From Table 10, it is noticed that the structure has better water proof property while its air permeability remains unchanged or is decreased, since its pore size is too small.

### Comparative Example 2-2

One surface of a symmetric porous structure having a porosity of 70%, a thickness of 50 μm and a pore size of 0.05 to 0.08 μm was cooled while the other surface was heated as shown in the following Table. The results are shown in Table 11.

TABLE 11

| | Heat treatment temperature (° C.) | | | | | |
|---|---|---|---|---|---|---|
| | Unheated | 260 | 300 | 340 | 380 | 400 |
| Thickness of | 49 | 49 | 50 | 51 | 51 | 41 |
| film (μm) | | | | | | |
| Porosity (%) | 70 | 70 | 70 | 72 | 71 | 52 |
| Pore size (μm) | 0.05 to | 0.05 to | 0.03 to | 0.02 to | 0.01 to | 0.01 to |
| | 0.08 | 0.08 | 0.08 | 0.08 | 0.08 | 0.05 |
| Water contact | 117 | 120 | 121 | 128 | 127 | 116 |
| angle (°) | | | | | | |
| Frazier air | 9.8 | 10.5 | 9.1 | 9.4 | 10.2 | 6.9 |
| permeability | | | | | | |
| (ft³/minft²) | | | | | | |
| Frazier air | 1 | 1.071 | 0.929 | 0.959 | 1.041 | 0.704 |
| permeability | | | | | | |
| index | | | | | | |
| Collecting | 99.24 | 99.49 | 99.94 | 99.99 | 99.99 | 99.99 |
| efficiency (%) | | | | | | |
| Water | 7000 | 8800 | >10000 | >10000 | >15000 | >15000 |
| pressure | | | | | | |
| resistance | | | | | | |
| (mmH₂O) | | | | | | |

From Table 11, it is noticed that the structure has better water proof property while its air permeability remains unchanged or is decreased, since its pore size is too small.

### Comparative Example 2-3

One surface of a symmetric porous structure having a porosity of 80%, a thickness of 50 μm and a pore size of 0.05 to 0.08 μm was cooled while the other surface was heated as shown in the following Table. The results are shown in Table 12.

TABLE 12

| | Heat treatment temperature (° C.) | | | | | |
|---|---|---|---|---|---|---|
| | Unheated | 260 | 300 | 340 | 380 | 400 |
| Thickness of | 47 | 47 | 48 | 48 | 48 | 39 |
| film (μm) | | | | | | |
| Porosity (%) | 80 | 80 | 81 | 82 | 81 | 55 |
| Pore size (μm) | 0.05 to | 0.04 to | 0.03 to | 0.02 to | 0.02 to | 0.01 to |
| | 0.08 | 0.08 | 0.08 | 0.08 | 0.08 | 0.03 |
| Water contact | 119 | 120 | 126 | 132 | 131 | 119 |
| angle (°) | | | | | | |
| Frazier air | 10.2 | 11.1 | 9.8 | 12.1 | 11.2 | 7.1 |
| permeability | | | | | | |
| (ft³/minft²) | | | | | | |
| Frazier air | 1 | 1.088 | 0.961 | 1.186 | 1.098 | 0.696 |
| permeability | | | | | | |
| index | | | | | | |
| Collecting | 99.24 | 99.49 | 99.94 | 99.99 | 99.99 | 99.99 |
| efficiency (%) | | | | | | |
| Water | 6,500 | 8,600 | >10,000 | >10,000 | >15,000 | >15,000 |
| pressure | | | | | | |
| resistance | | | | | | |
| (mmH₂O) | | | | | | |

From Table 12, it is noticed that the structure has better water proof property while its air permeability remains unchanged or is decreased, since its pore size is too small.

### Comparative Example 3-1

One surface of a symmetric porous structure having a porosity of 86%, a thickness of 22 μm and a pore size of 0.20 to 0.45 μm was cooled while the other surface was heated as shown in the following Table. Further, the obtained asymmetric porous structure was dyed and subjected to oil repellent process. The dyeing was carried out by immersing the structure into a fluoropolymer dye dissolved in isopropanol, and the oil repellent process was carried out by use of a known oil repellent agent. The results are shown in Table 13.

TABLE 13

| Heat treatment temperature (° C.) | | unheated | 300 |
|---|---|---|---|
| Thickness of film (μm) | | 22 | 20 |
| Porosity (%) | | 86 | 86 |
| Pore size (μm) | | 0.21 to | 0.19 to 0.45 |
| | | 0.45 | |
| Water pressure | Before dyeing | 5,500 | 12,000 |
| resistance | After dyeing | 7,000 | 12,500 |
| (mmH₂O) | | | |
| Gurley number | Before dyeing | 3.9 | 4 |
| (second) | After dyeing | 4.5 | 4.1 |
| Sound | Before dyeing | 0.8 | 1 |
| transmission | After dyeing | 1.2 | 1.1 |
| loss (dB) | | | |
| Oil rating | Before oil repellent | 0 | 0 |
| | process | | |
| | After oil repellent | 2 | 4 |
| | process | | |

From Table 13, it is noticed that the dyeing and the oil repellent process do not have a significant influence on water-proof property, dust-proof property, sound transmission capability and air permeability.

### Example 3-2

One surface of a symmetric porous structure having a porosity of 90%, a thickness of 11 μm and a pore size of 0.72 to 1.3 μm was cooled while the other surface was heated as shown in the following Table. Further, the obtained asymmetric porous structure was dyed and subjected to oil repellent process. The results are shown in Table 14.

TABLE 14

| | | |
|---|---|---|
| Heat treatment temperature (° C.) | unheated | 300 |
| Thickness of film (μm) | 11 | 10 |
| Porosity (%) | 90 | 90 |
| Pore size (μm) | 0.72 to 1.3 | 0.10 to 1.3 |

| | | | |
|---|---|---|---|
| Water pressure | Before dyeing | 1,000 | 8,000 |
| resistance | After dyeing | 3,000 | 8,500 |
| (mmH₂O) | | | |
| Gurley number | Before dyeing | 0.3 | 0.5 |
| (second) | After dyeing | 0.7 | 0.5 |
| Sound | Before dyeing | 0.5 | 0.5 |
| transmission | After dyeing | 0.8 | 0.5 |
| loss (dB) | | | |
| Oil rating | Before oil | 0 | 0 |
| | repellent process | | |
| | After oil repellent | 2 | 4 |
| | process | | |

From Table 14, it is noticed that the dyeing and the oil repellent process do not have a significant influence on water-proof property, dust-proof property, sound transmission capability and air permeability.

### Example 5

An original PTFE film was expanded in the machine direction (MD) at an expanding ratio of 1:8 under an environment of 320° C., and subsequently expanded in the transverse direction (TD) at an expanding ratio of 1:3 under an environment of 320° C. The obtained symmetric porous structure was heated (heating temperature: 270° C.) with heated rollers (diameter 250 mm×length 2 m) as shown in FIG. 4 (b) and subsequently expanded in the transverse direction (TD) at an expanding ratio of 1:6 under an environment of 380° C. This asymmetric porous structure was heated (heating temperature: 270° C.) with heated rollers (diameter 250 mm×length 2 m) as shown in FIG. 4 (b). The results are shown in Table 15.

### Example 6

An original PTFE film was expanded in the machine direction (MD) at an expanding ratio of 1:8 under an environment of 320° C., and subsequently expanded in the transverse direction (TD) at an expanding ratio of 1:3 under an environment of 320° C. The obtained symmetric porous structure was heated (heating temperature: 270° C.) with heated rollers (diameter 250 mm×length 2 m) as shown in FIG. 4 (b) and subsequently expanded in the transverse direction (TD) at an expanding ratio of 1:5 under an environment of 380° C. This asymmetric porous structure was heated (heating temperature: 270° C.) with heated rollers (diameter 250 mm×length 2 m) as shown in FIG. 4 (b). The results are shown in Table 15.

### Example 7

An original PTFE film was expanded in the machine direction (MD) at an expanding ratio of 1:8 under an environment of 320° C., and subsequently expanded in the transverse direction (TD) at an expanding ratio of 1:3 under an environment of 320° C. The obtained symmetric porous structure was heated (heating temperature: 270° C.) with heated rollers (diameter 250 mm×length 2 m) as shown in FIG. 4 (b) and subsequently expanded in the transverse direction (TD) at an expanding ratio of 1:3 under an environment of 380° C. This asymmetric porous structure was heated (heating temperature: 270° C.) with heated rollers (diameter 250 mm×length 2 m) as shown in FIG. 4 (b). The property of the obtained asymmetric porous structure was evaluated. The results are shown in Table 15.

### Example 8

An original PTFE film was expanded in the machine direction (MD) at an expanding ratio of 1:8 under an environment of 320° C., and subsequently expanded in the transverse direction (TD) at an expanding ratio of 1:10 under an environment of 320° C. The obtained symmetric porous structure was heated (heating temperature: 270° C.) with heated rollers (diameter 250 mm×length 2 m) as shown in FIG. 4 (b). The property of the obtained asymmetric porous structure was evaluated. The results are shown in Table 15.

### Comparative Example 1

An original PTFE film was expanded in the machine direction (MD) at an expanding ratio of 1:8 under an environment of 320° C., and subsequently expanded in the transverse direction (TD) at an expanding ratio of 1:6 under an environment of 320° C. The property of the obtained symmetric porous structure was evaluated. The results are shown in Table 15.

### Comparative Example 2

An original PTFE film PTFE porous structure was expanded in the machine direction (MD) at an expanding ratio of 1:8 under an environment of 320° C., and subsequently expanded in the transverse direction (TD) at an expanding ratio of 1:8 under an environment of 320° C. The property of the obtained symmetric porous structure was evaluated. The results are shown in Table 15.

TABLE 15

| | | | | Single | | |
|---|---|---|---|---|---|---|
| | Two time expanding in the | | | expanding in | Symmetric film | |
| | transverse direction | | | the transverse | Compar- | Compar- |
| | (asymmetric film) | | | direction | ative | ative |
| | Example | Example | Example | (asymmetric film) | Example | Example |
| | 5 | 6 | 7 | Example 8 | 1 | 2 |
| Average pore | 1.0 | 0.7 | 0.5 | 1.2 | 1.0 | 1.0 |
| size (μm) | | | | | | |
| Pore size | 1.2 | 0.9 | 0.7 | 1.5 | 1.3 | 1.4 |
| (μm) | | | | | | |
| Porosity (%) | 91 | 87 | 88 | 77 | 88 | 93 |
| Thickness | 18 | 19 | 19 | 25 | 20 | 22 |
| (μm) | | | | | | |
| Frazier air | 51.4 | 45.4 | 36.1 | 39.2 | 27.2 | 36.1 |
| permeability | | | | | | |
| (ft³/minft²) | | | | | | |
| Water | 14,000 | 14,000 | 15,000 | 14,000 | 5,000 | 3,000 |
| pressure | | | | | | |
| resistance | | | | | | |
| (mmH₂O) | | | | | | |
| Gurley | 0.6 | 0.7 | 1.1 | 0.8 | 0.9 | 0.5 |
| number | | | | | | |
| (second) | | | | | | |
| Sound | 0.5 | 0.6 | 1.1 | 0.7 | 0.4 | 0.5 |
| transmission | | | | | | |
| loss (dB) | | | | | | |
| Frazier air | 1.89 | 1.67 | 1.33 | 1.44 | 1 | |
| flow | | | | | | |
| rate ratio | | | | | | |

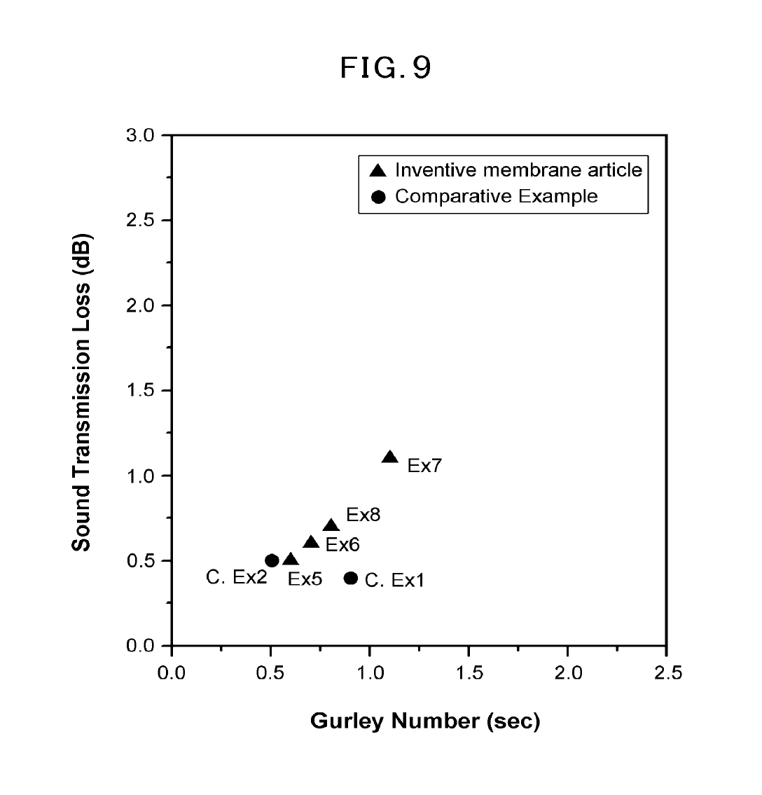

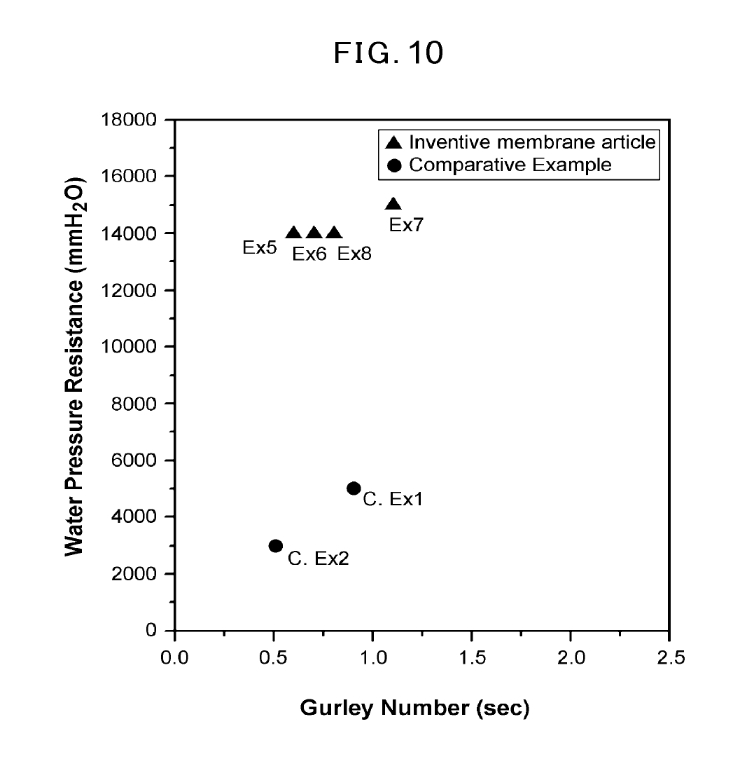

In addition, regarding Examples 5 to 8, the relation between Gurley number and sound transmission loss coefficient and the relation between Gurley number and water pressure resistance were evaluated. The results are shown in FIGS. 9 and 10. From FIG. 9, it can be noticed that the sound transmission loss decreases a little as the Gurley number increases (the amount of air permeation decreases) in the conventional film. On the other hand, in the asymmetric film of the present invention, it is noticed that when the Gurley number increases (the amount of air permeation decreases), the sound transmission loss also increases while the proportion of increase thereof is extremely small.

Further, from FIG. 10, it is noticed that the water pressure resistance increases as the Gurley number increases (the amount of air permeation decreases) in the conventional film. On the other hand, in the asymmetric film of the present invention, it is noticed that the water pressure resistance hardly changes even if the Gurley number increases (the amount of air permeation decreases).

From the above, it is recognized that according to the membrane of the present invention, water proof property can be improved without deteriorating air permeability and sound transmission capability.

Additionally, it is also recognized that the heating process may be once or twice.

1-15. (canceled)

16. A water-proof and dust-proof membrane assembly comprising:
a body comprising an asymmetric porous structure in the form of a membrane having a first surface and a second surface, wherein said asymmetric porous structure comprises at least one pore, and wherein said asymmetric porous structure comprises a thickness in the range of 1 μm to 1000 μm, a first porosity in the range of 5% to 90%, a pore size of each pore is the range of 0.01 μm to 15 μm, a Frazier air permeability in the range of 8.0 ft³/minft² to 250 ft³/minft², a Gurley number in the range of 0.3 seconds to 25 seconds, a water resistance in the range of 1000 mmH₂O to 23000 mmH₂O, and a sound transmission loss in the range of 0.5 dB to 2.0 dB; and
a supporting member comprising a polymeric material; a first contact surface; and a second contact surface, wherein said supporting material comprises a second porosity that is larger than said first porosity of said asymmetric porous structure of said body, and wherein said first surface of said body and said first contact surface of said supporting member are bonded.

17. The water-proof and dust-proof membrane assembly of claim 16, wherein said asymmetric porous structure comprises a skin layer and a continuously foamed porous layer, and wherein said skin layer constitutes a range of 0.04% to 40% of a thickness of said asymmetric porous structure.

18. The water-proof and dust-proof membrane assembly of claim 17, wherein a water contact angle of said skin layer is in the range of 120° to 135°.

19. The water-proof and dust-proof membrane assembly of claim 17, wherein said skin layer is configured on either of said first surface or said second surface of said asymmetric porous structure, and wherein said asymmetric porous structure comprises a Frazier air permeability in the range of 8.0 ft³/minft² to 200 ft³/minft², a Gurley number in the range of 0.3 seconds to 25 seconds, a water resistance in the range of 1000 mmH₂O to 18000 mmH₂O, and a sound transmission loss in the range of 0.5 dB to 2.0 dB.

20. The water-proof and dust-proof membrane assembly of claim 17, wherein said skin layer is configured on either of said first surface or said second surface of said asymmetric porous structure, and wherein said asymmetric porous structure comprises a Frazier air permeability in the range of 15 ft³/minft² to 250 ft³/minft², a Gurley number in the range of 0.3 seconds to 25 seconds, a water resistance in the range of 11000 mmH₂O to 23000 mmH₂O, and a sound transmission loss in the range of 0.5 dB to 1.5 dB.

21. The water-proof and dust-proof membrane assembly of claim 16, wherein said asymmetric porous structure is produced by heat-treating a symmetric porous structure and a variation of said Frazier air permeability thereof after a heat treatment is in the range of 1.1 to 2.5 times that before said heat treatment.

22. The water-proof and dust-proof membrane assembly of claim 16, wherein said asymmetric porous structure comprises a collecting efficiency in the range of 99.50% to 99.99%.

23. The water-proof and dust-proof membrane assembly of claim 17, wherein said skin layer is configured on either of said first surface or said second surface of said asymmetric porous structure, and wherein said asymmetric porous structure comprises a Frazier air permeability in the range of 6 ft³/minft² to 183 ft³/minft², a Gurley number in the range of 0.25 seconds to 25 seconds, a water resistance in the range of 3000 mmH₂O to 20000 mmH₂O, and a sound transmission loss in the range of 0.7 dB to 3.0 dB.

24. The water-proof and dust-proof membrane assembly of claim 17, wherein said skin layer is configured on either of said first surface or said second surface of said asymmetric porous structure, and wherein said asymmetric porous structure comprises a Frazier air permeability in the range of 12.6 ft³/minft² to 220 ft³/minft², a Gurley number in the range of 0.3 seconds to 25 seconds, a water resistance in the range of 13000 mmH₂O to 25000 mmH₂O, and a sound transmission loss in the range of 0.7 dB to 3.0 dB.

25. The water-proof and dust-proof membrane assembly of claim 16, wherein said body is formed by a film comprises any of a resin porous film and a fluorine polymer film.

26. The water-proof and dust-proof membrane assembly of claim 25, wherein said resin porous film comprises any of an ultrahigh molecular weight porous polyethylene film and a porous polytetrafluoroethylene film.

27. The water-proof and dust-proof membrane assembly of claim 25, wherein said fluorine polymer film comprises any of a partially fluorinated polymer and a completely fluorinated polymer.

28. An electronic device comprising:
a housing comprising at least one opening;
at least one electronic circuit component operatively connected to said housing; and
a water-proof and dust-proof membrane assembly located over said at least one opening, wherein said water-proof and dust-proof membrane assembly comprising:
a body comprising an asymmetric porous structure in the form of a membrane having a first surface and a second surface, wherein said asymmetric porous structure comprises at least one pore, and wherein said asymmetric porous structure comprises a thickness in the range of 1 μm to 1000 μm, a first porosity in the range of 5% to 90%, a pore size of each pore is the range of 0.01 μm to 15 μm, a Frazier air permeability in the range of 8.0 ft³/minft² to 250 ft³/minft², a Gurley number in the range of 0.3 seconds to 25 seconds, a water resistance in the range of 1000 mmH₂O to 23000 mmH₂O, and a sound transmission loss in the range of 0.5 dB to 2.0 dB; and
a supporting member comprising a polymeric material; a first contact surface; and a second contact surface, wherein said supporting material comprises a second porosity that is larger than said first porosity of said asymmetric porous structure of said body, and wherein said first surface of said body and said first contact surface of said supporting member are bonded.

29. A lighting system comprising:
a cover comprising at least one opening;
a hollow housing comprising a window portion mating with said cover;
at least one light source device located inside said hollow housing and configured to align with said at least one opening; and
a water-proof and dust-proof membrane assembly located over said at least one opening, wherein said water-proof and dust-proof membrane assembly comprising:
a body comprising an asymmetric porous structure in the form of a membrane having a first surface and a second surface, wherein said asymmetric porous structure comprises at least one pore, and wherein said asymmetric porous structure comprises a thickness in the range of 1 μm to 1000 μm, a first porosity in the range of 5% to 90%, a pore size of each pore is the range of 0.01 μm to 15 μm, a Frazier air permeability in the range of 8.0 ft³/minft² to 250 ft³/minft², a Gurley number in the range of 0.3 seconds to 25 seconds, a water resistance in the range of 1000 mmH₂O to 23000 mmH₂O, and a sound transmission loss in the range of 0.5 dB to 2.0 dB; and
a supporting member comprising a polymeric material; a first contact surface; and a second contact surface, wherein said supporting material comprises a second porosity that is larger than said first porosity of said asymmetric porous structure of said body, and wherein said first surface of said body and said first contact surface of said supporting member are bonded.

30. A container comprising:
a cover comprising at least one opening;
a hollow housing comprising a window portion mating with said cover; and
a water-proof and dust-proof membrane assembly located over said at least one opening, wherein said water-proof and dust-proof membrane assembly comprising:
a body comprising an asymmetric porous structure in the form of a membrane having a first surface and a second surface, wherein said asymmetric porous structure comprises at least one pore, and wherein said asymmetric porous structure comprises a thickness in the range of 1 μm to 1000 μm, a first porosity in the range of 5% to 90%, a pore size of each pore is the range of 0.01 μm to 15 μm, a Frazier air permeability in the range of 8.0 ft³/minft² to 250 ft³/minft², a Gurley number in the range of 0.3 seconds to 25 seconds, a water resistance in the range of 1000 mmH₂O to 23000 mmH₂O, and a sound transmission loss in the range of 0.5 dB to 2.0 dB; and
a supporting member comprising a polymeric material; a first contact surface; and a second contact surface, wherein said supporting material comprises a second porosity that is larger than said first porosity of said asymmetric porous structure of said body, and wherein said first surface of said body and said first contact surface of said supporting member are bonded.
